(19) United States
(12) Patent Application Publication
(10) Pub. No.: US 2026/0198082 A1
(43) Pub. Date: Jul. 9, 2026

(54) SEMICONDUCTOR DEVICE AND METHOD

(71) Applicant: Taiwan Semiconductor Manufacturing Co., Ltd., Hsinchu (TW)

(72) Inventors: Tsai-Jung Ho, Xihu Township (TW); Meng-Ku Chen, New Taipei (TW); Ching-Feng Fu, Taichung (TW); Han Han, Hsinchu (TW)

(21) Appl. No.: 19/223,440

(22) Filed: May 30, 2025

Related U.S. Application Data
(60) Provisional application No. 63/743,421, filed on Jan. 9, 2025.

(51) Int. Cl. H10D 84/85; H10D 84/01

(52) U.S. Cl. CPC H10D 84/851; H10D 84/0167; H10D 84/017; H10D 84/0186; H10D 84/0188

(57) ABSTRACT

A semiconductor device and the method of forming the same are provided. The semiconductor device may include a source/drain region, a first nanostructure along a sidewall of the source/drain region, a gate structure wrapping around the first nanostructure, a first gate spacer along a sidewall of a first portion of the gate structure, a first dielectric layer over the source/drain region and the gate structure, a first conductive contact extending through the first dielectric layer and electrically connected to the source/drain region, and a first dielectric liner along a sidewall of the first conductive contact. The first dielectric liner may extend from a level of a top surface of the first conductive contact to a top surface of the source/drain region. The first dielectric liner may be in contact with a sidewall of the first gate spacer.

### PRIORITY CLAIM AND CROSS-REFERENCE

This application claims the benefit of U.S. Provisional Application No. 63/743,421, filed on Jan. 9, 2025, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 10C, 11A, 11B, 11C, 12, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, 22C, 23A, 23B, 23C, 24A, 24B, and 24C are views of intermediate processes in the manufacturing of a semiconductor device including nano-FETs, in accordance with some embodiments.

FIGS. 25A, 25B, 25C, 26A, 26B, 26C, 27A, 27B, and 27C are views of intermediate processes in the manufacturing of a semiconductor device including nano-FETs, in accordance with some embodiments.

FIGS. 28A, 28B, 28C, 29A, 29B, 29C, 30A, 30B, and 30C are views of intermediate processes in the manufacturing of a semiconductor device including nano-FETs, in accordance with some embodiments.

FIGS. 31A, 31B, and 31C are views of a semiconductor device including nano-FETs, in accordance with some embodiments.

FIGS. 32A, 32B, and 32C are views of a semiconductor device including nano-FETs, in accordance with some embodiments.

FIGS. 33A, 33B, and 33C are views of a semiconductor device including nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor device and methods of forming the same. The semiconductor device may include a stack of nanostructures, a gate structure wrapping around each nanostructure of the stack of nanostructures, a source/drain region on sidewalls of the stack of nanostructures, a conductive contact over the source/drain region. The semiconductor device may further include a spacer between an upper portion of the gate structure and the conductive contact. By at least partially removing of the portions of the source/drain regions from sidewall of the spacer and adding one or more dielectric liners on the sidewall of the spacer, sufficient electrical insulation may be established between the conductive contact and the gate structure, thereby eliminating or reducing parasitic capacitance between the conductive contact and the gate structure. As a result, the performance and reliability of the semiconductor device may be improved.

Some embodiments discussed herein are described in the context of a semiconductor device including nano-FETs. However, various embodiments may be applied to dies including other types of transistors (e.g., fin field effect transistors (FinFETs), vertical field-effect transistors (VFETs), complementary field-effect transistors (CFETs), planar transistors, or the like) in lieu of or in combination with the nano-FETs.

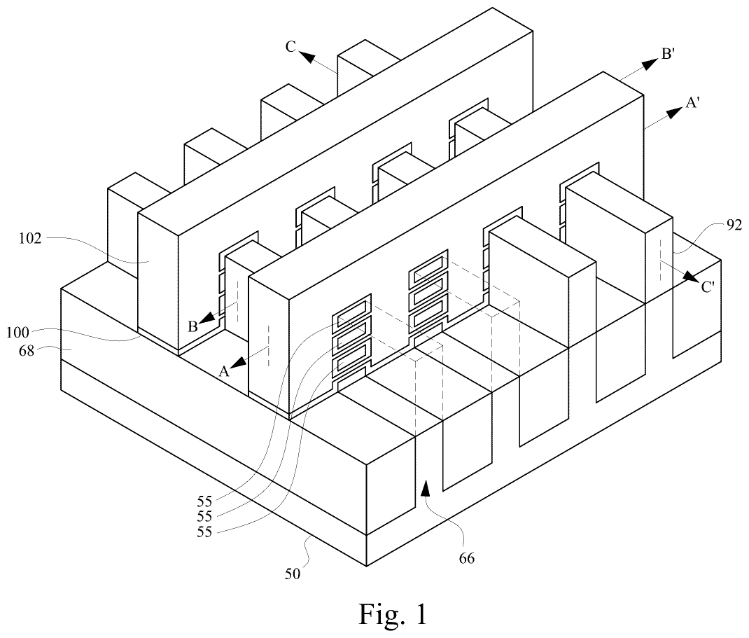

FIG. 1 illustrates an example of nano-FETs (e.g., nanowire FETs, nanosheet FETs, or the like) in a three-dimensional view. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68. Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Reference cross-section A-A′ is along a longitudinal axis of a gate electrode 102 and in a direction, for example, perpendicular to the direction of current flow between the epitaxial source/drain regions 92 of a nano-FET. Reference cross-section B-B′ is parallel to the reference cross-section A-A′ and extends through epitaxial source/drain regions 92 of multiple nano-FETs. Reference cross-section C-C′ is perpendicular to the reference cross-section A-A′ and is parallel to a longitudinal axis of a fin 66 of the nano-FET and in a direction of, for example, a current flow between the epitaxial source/drain regions 92 of the nano-FET. Reference cross-section D-D′ is parallel to the reference cross-section C-C′ and extends through multiple gate electrodes 102. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in FinFETs.

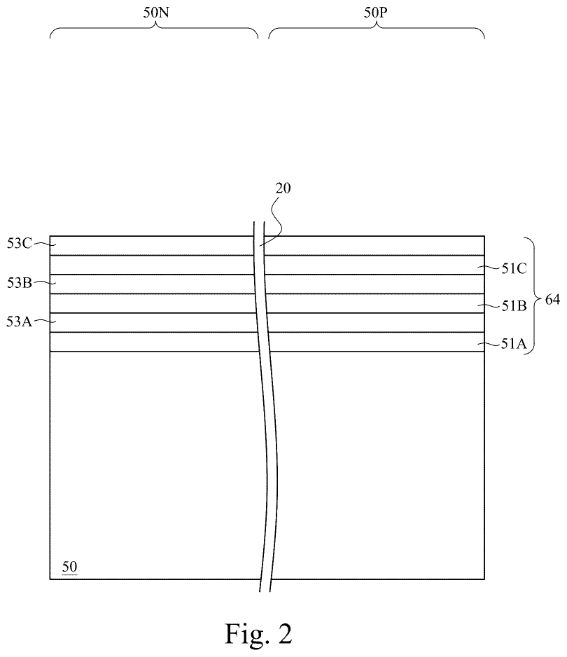

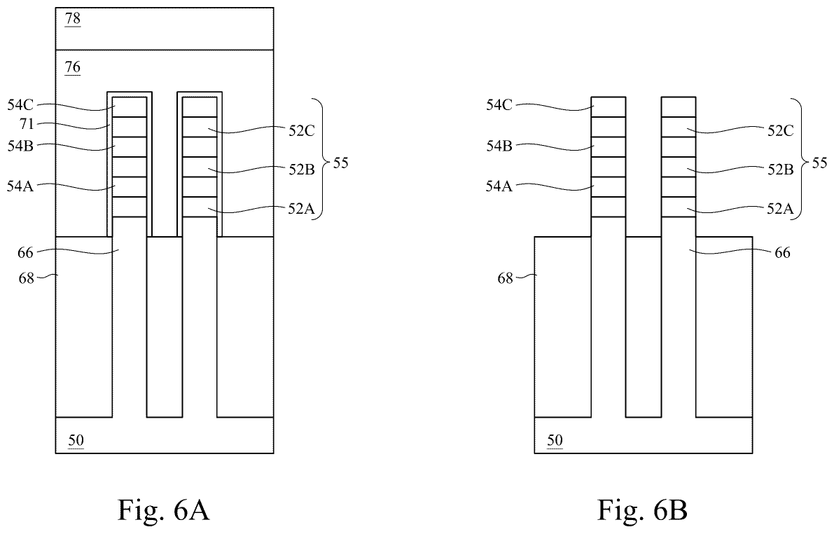

FIGS. 2 through 24C are views of intermediate processes in the manufacturing of a semiconductor device including nano-FET devices, in accordance with some embodiments. FIGS. 2, 3, 4, 5, 6A, 7A, 8A, 9A, 10A, 11A, 12, 13A, 14A, 15A, 16A, 17A, 18A, 19A, 20A, 21A, 22A, 23A, and 24A illustrate cross-sectional views along the reference cross-section A-A′ illustrated in FIG. 1. FIGS. 6B, 7B, 8B, 9B, 10B, 11B, 13B, 14B, 15B, 16B, 17B, 18B, 19B, 20B, 21B, 22B, 23B, and 24B illustrate cross-sectional views along the reference cross-section B-B′ illustrated in FIG. 1. FIGS. 6C, 7C, 8C, 9C, 10C, 11C, 13C, 14C, 15C, 16C, 17C, 18C, 19C, 20C, 21C, 22C, 23C, and 24C illustrate cross-sectional views along the reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 may be removed and the second semiconductor layers 53 may be patterned to form channel regions of nano-FETs in the n-type region 50N and the p-type region 50P. In some embodiments, the first semiconductor layers 51 are removed and the second semiconductor layers 53 are patterned to form channel regions of nano-FETs in the n-type region 50N, and the second semiconductor layers 53 are removed and the first semiconductor layers 51 are patterned to form channel regions of nano-FETs in the p-type region 50P. In some embodiments, the second semiconductor layers 53 are removed and the first semiconductor layers 51 are patterned to form channel regions of nano-FETs in the n-type region 50N, and the first semiconductor layers 51 are removed and the second semiconductor layers 53 are patterned to form channel regions of nano-FETs in the p-type region 50P. In some embodiments, the second semiconductor layers 53 are removed and the first semiconductor layers 51 are patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon or the like.

The first semiconductor materials and the second semiconductor materials may be materials having a high etching selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

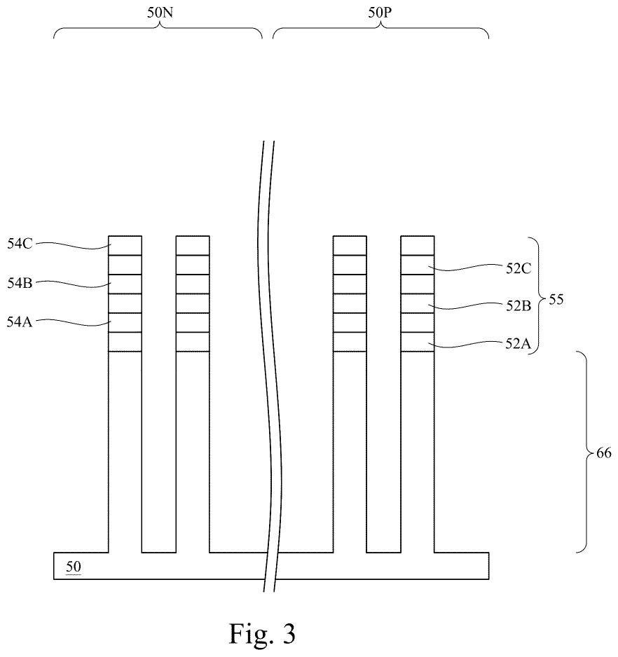

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

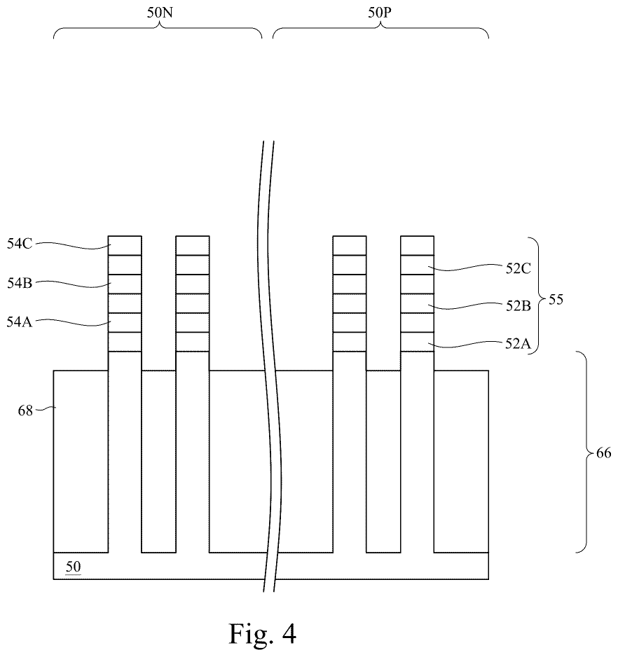

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, such as silicon nitride, the like, or a combination thereof, and may be formed by high-density plasma CVD (HDP-CVD), flowable CVD (FCVD), the like, or a combination thereof. Other insulation materials formed by any acceptable process may be used. An anneal process may be performed once the insulation material is formed. Although the insulation material is illustrated as a single layer, some embodiments may utilize multiple layers.

A removal process may be then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material may be substantially co-planar or level after the planarization process is complete. The insulation material may be then recessed to form the STI regions 68. The insulation material may be recessed such that upper portions of fins 66 in the n-type region 50N and the p-type region 50P protrude from between neighboring STI regions 68. The STI regions 68 may be recessed using an acceptable etching process, such as one that is selective to the material of the insulation material and etches the material of the insulation material at a faster rate than the material of the fins 66 and the nanostructures 55. For example, dilute hydrofluoric acid may be used when the insulation material is an oxide. After the removal process, the top surfaces of the STI regions 68 may have a flat surface as illustrated, a convex surface, a concave surface, or a combination thereof.

The process described above with respect to FIGS. 2 through 4 is one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) are illustrated and discussed herein as comprising the same materials in the p-type region 50P and the n-type region 50N, and the second semiconductor layers 53 (and resulting second nanostructures 54) are illustrated and discussed herein as comprising the same materials in the p-type region 50P and the n-type region 50N for illustrative purposes. In some embodiments, the first semiconductor layers 51 may comprise different materials in the p-type region 50P and the n-type region 50N. In some embodiments, the second semiconductor layers 53 may comprise different materials in the p-type region 50P and the n-type region 50N. In some embodiments, the first semiconductor layers 51 may comprise different materials in the p-type region 50P and the n-type region 50N, and the second semiconductor layers 53 may comprise different materials in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implantation, the photoresist may be removed, such as by an acceptable ashing process. After the implantations of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

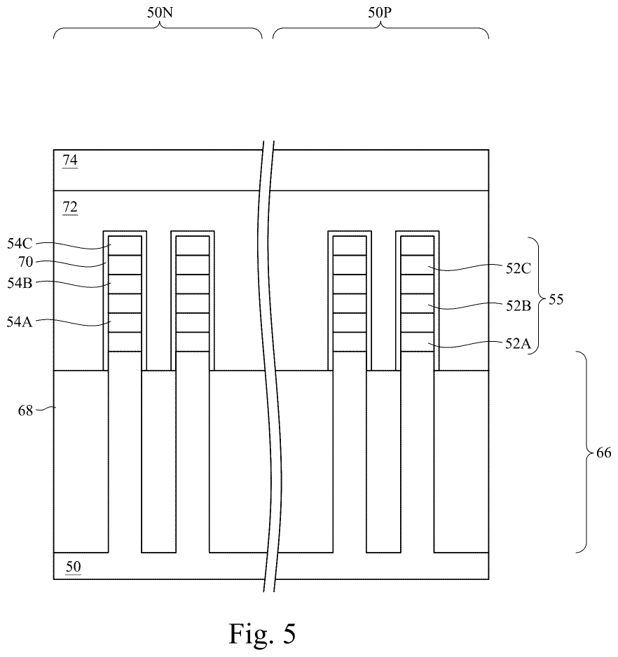

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity to the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 24C illustrate various additional processes in the manufacturing of the nano-FET devices, in accordance to some embodiments. FIGS. 6A through 24C illustrate features in either or both the n-type region 50N or the p-type region 50P. In FIGS. 6A through 6C, masks 78, dummy gates 76, and dummy gate dielectrics 71 are formed. The dummy gates 76 and dummy gate dielectrics 71 may be collectively referred to as dummy gate structures. The mask layer 74 (see FIG. 5) may be patterned using suitable photolithography and etching processes to form the masks 78. The pattern of the masks 78 then may be transferred to the dummy gate layer 72 and to the dummy dielectric layer 70 to form the dummy gates 76 and the dummy gate dielectrics 71, respectively, using suitable etching processes. The dummy gates 76 cover respective channel regions of the fins 66 and the overlying respective nanostructures 55. The pattern of the masks 78 may be used to separate each of the dummy gates 76 from adjacent dummy gates 76. The dummy gates 76 may also have a lengthwise direction substantially perpendicular to the lengthwise direction of respective fins 66.

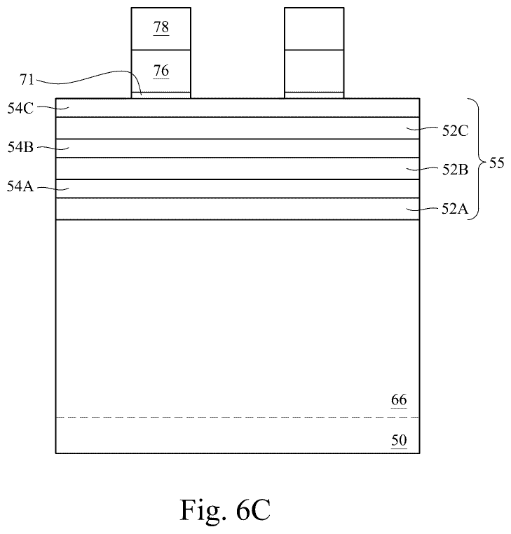

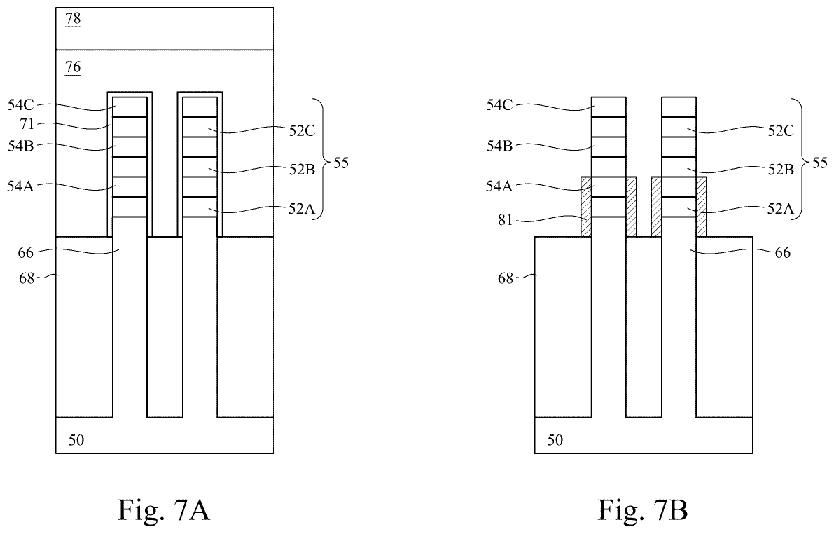

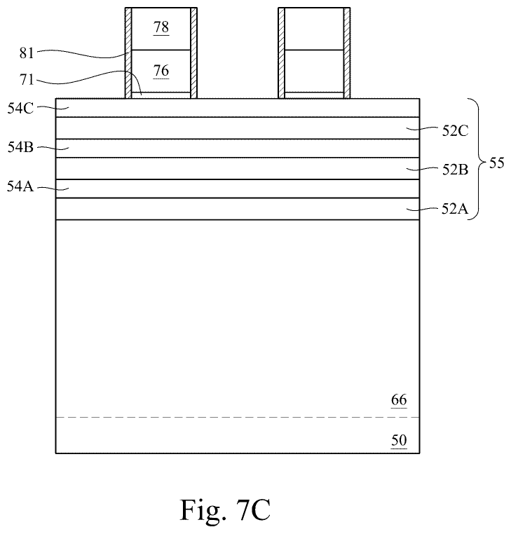

In FIGS. 7A through 7C, spacers 81 are formed. Spacers 81 may be also referred to as gate spacers. The spacers 81 may self-align subsequently formed source/drain regions, as well as protect the dummy gate dielectrics 71 and the dummy gate 76 during subsequent etching processes. The spacers 81 may be a single layer of one material or multiple sub-layers of different materials with different etch rates. In some embodiments, the spacers 81 comprise two sub-layers with different materials of different etch rates, which may be selected from silicon oxide, silicon nitride, silicon oxynitride, or the like. The spacers 81 may be formed by forming a spacer layer by thermal oxidation or a suitable deposition process, such as CVD, ALD, or the like, and then patterning the spacer layer by a suitable etching process, such as an isotropic etching process (e.g., a wet etching process), an anisotropic etching process (e.g., a dry etching process), or the like.

The spacer layer may be formed on top surfaces of the STI regions 68; top surfaces and sidewalls of the fins 66, the nanostructures 55, and the masks 78; and sidewalls of the dummy gates 76 and the dummy gate dielectrics 71. After the etching process, the spacers 81 may remain on the top surfaces of the STI regions 68, and the sidewalls of the fins 66 and nanostructures 55 as illustrated in FIG. 7B. After the etching process, the spacers 81 may remain on the top surfaces of the nanostructures 55, and the sidewalls of the masks 78, the dummy gates 76, and the dummy gate dielectrics 71 as illustrated in FIG. 7C.

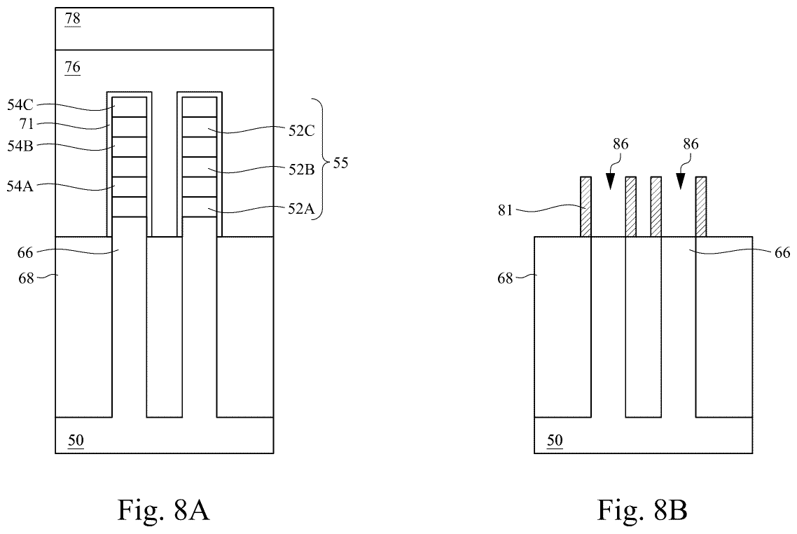

In FIGS. 8A through 8C, first recesses 86 are formed in the fins 66 and the nanostructures 55. The first recesses 86 may extend through the first nanostructures 52 and the second nanostructures 54, and into the fins 66. As illustrated in FIG. 8B, top surfaces of the STI regions 68 (e.g., top surfaces of the fins 66) may be level with bottom surfaces of the first recesses 86. In some embodiments, the bottom surfaces of the first recesses 86 are disposed below the top surfaces of the STI regions 68. The first recesses 86 may be formed by partially removing the fins 66 and the nanostructures 55 using anisotropic etching processes, such as RIE, NBE, or the like. The spacers 81 and the masks 78 may mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching after the first recesses 86 reach desired depths.

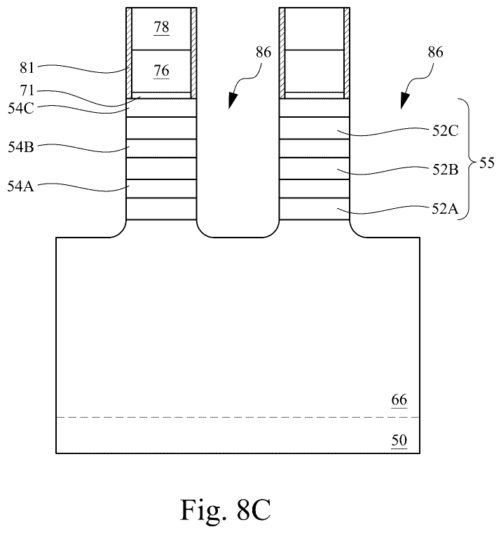

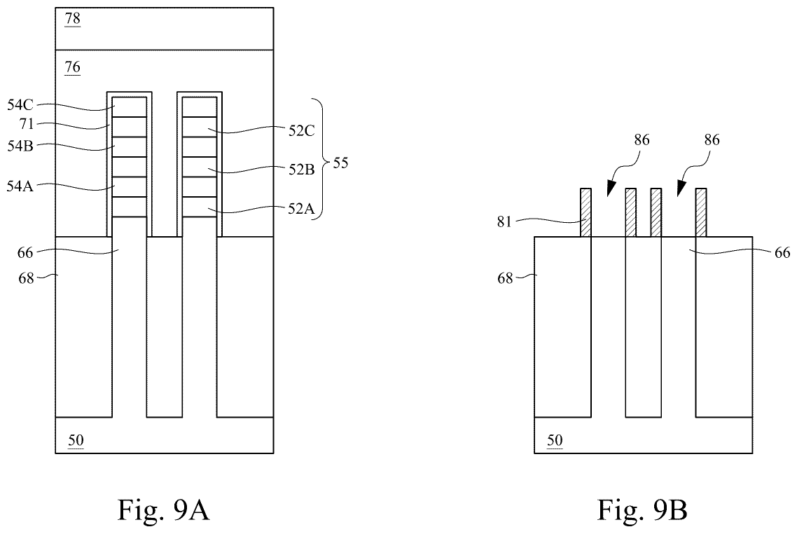

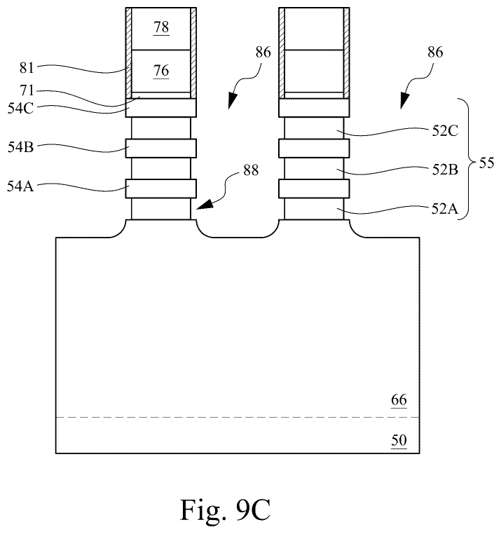

In FIGS. 9A through 9C, portions of the first nanostructures 52 exposed by the first recesses 86 are etched to form second recesses 88. Although sidewalls of the first nanostructures 52 adjacent the second recesses 88 are illustrated as being straight in FIG. 9C, the sidewalls may be concave or convex. The first nanostructures 52 may be etched using isotropic etching processes, such as wet etching or the like. In the embodiments in which the first nanostructures 52 comprise silicon-germanium or the like, and the second nanostructures 54 comprise silicon, silicon carbide, or the like, tetramethylammonium hydroxide (TMAH), ammonium hydroxide (NH₄OH), or the like may be used to etch the first nanostructures 52.

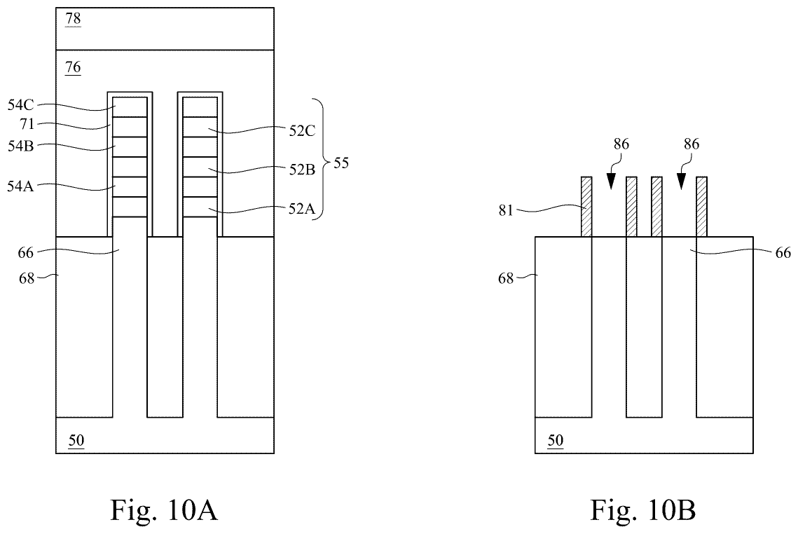

In FIGS. 10A through 10C, inner spacers 90 are formed in the second recesses 88. The inner spacers 90 may provide electrical insulation between the subsequently formed source/drain regions and the subsequently formed gate structures as discussed in greater details below. The inner spacers 90 may extend along sidewalls of the first nanostructures 52 and be in contact with the portions of the top surfaces and the bottom surfaces of the second nanostructures 54 previously exposed. The inner spacers 90 may be formed by depositing an inner spacer layer (not separately illustrated) over the structure shown in FIGS. 9A through 9C, and then etching the inner spacer layer. The inner spacer layer may be deposited by a suitable deposition process, such as CVD, ALD, or the like. The inner spacer layer may comprise a dielectric material, such as silicon nitride or the like. The material of inner spacer layer may have a dielectric constant (k) less than about 3.5. The inner spacer layer may be etched to form the inner spacers 90 by an anisotropic etching process, such as RIE, NBE, or the like. Outer sidewalls of the inner spacers 90 are illustrated in FIG. 10C as being straight and flush with sidewalls of the second nanostructures 54 as an example, the outer sidewalls of the inner spacers 90 may extend beyond (e.g., convex) or be recessed from (e.g., concave) the sidewalls of the second nanostructures 54 in some embodiments.

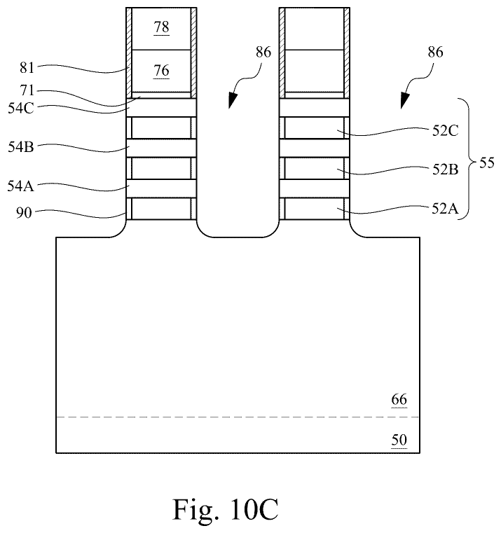

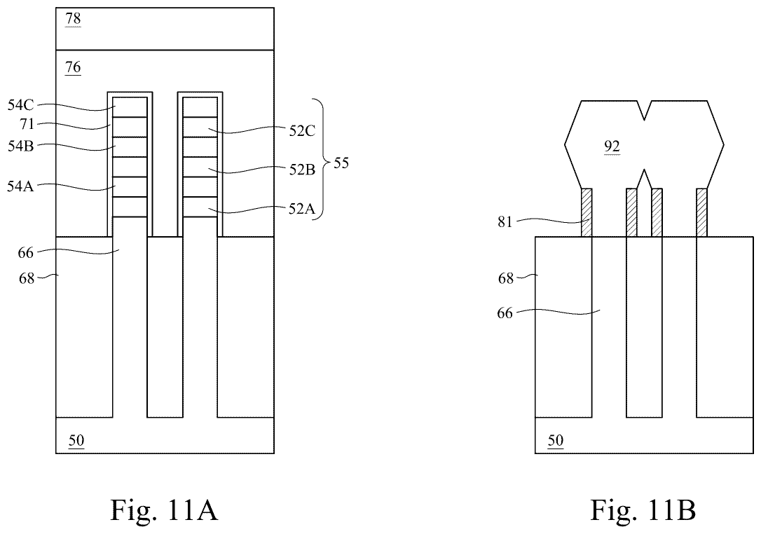

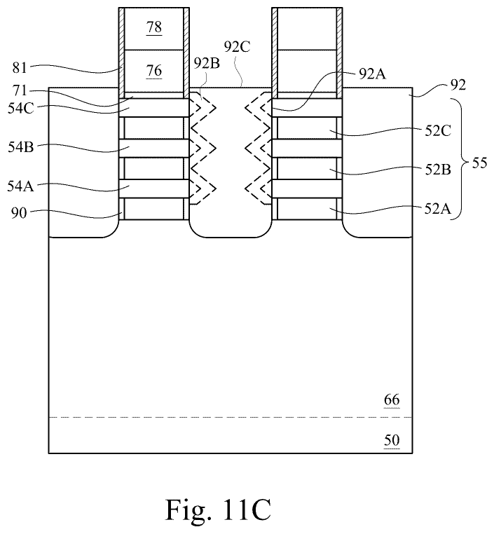

In FIGS. 11A through 11C, epitaxial source/drain regions 92 are formed in the first recesses 86. Epitaxial source/drain region(s) 92 may refer to a source or a drain, individually or collectively dependent upon the context. In some embodiments, the epitaxial source/drain regions 92 may exert stress on the second nanostructures 54, thereby improving performance. As illustrated in FIG. 11C, the epitaxial source/drain regions 92 are formed in the first recesses 86 such that each dummy gate 76 is disposed between respective neighboring pairs of the epitaxial source/drain regions 92. The epitaxial source/drain regions 92 may be on the sidewalls of the second nanostructures 54, the inner spacers 90, and the spacers 81. Top surfaces of the epitaxial source/drain regions 92 may be above the top surfaces of the second nanostructures 54C.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an annealing process. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

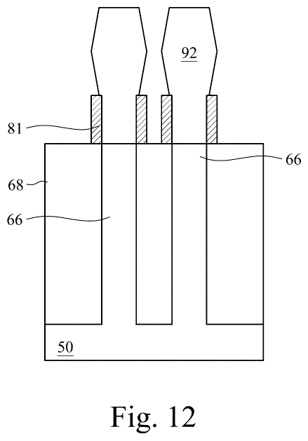

As a result of the epitaxy processes used to form the epitaxial source/drain regions 92 in the n-type region 50N and the p-type region 50P, upper portions of the epitaxial source/drain regions 92 may have facets which expand laterally outward beyond sidewalls of the nanostructures 55. In some embodiments, these facets cause adjacent epitaxial source/drain regions 92 of a same nano-FET to merge as illustrated by FIG. 11B. In some embodiments, adjacent epitaxial source/drain regions 92 remain separated after the epitaxy process is completed as illustrated by FIG. 12.

The epitaxial source/drain regions 92 may comprise one or more semiconductor material layers. In some embodiments, the epitaxial source/drain regions 92 comprise first liner layers 92A on the sidewalls of the second nanostructures 54, second liner layers 92B on the first liner layers 92A, and fill layers 92C on the second liner layers 92B, as shown in FIG. 11C. The first liner layers 92A, the second liner layers 92B, and the fill layers 92C may be formed of different semiconductor materials and/or may be doped to different dopant concentrations. The first liner layers 92A may be grown first, the second liner layers 92B may be grown on the first liner layers 92A, and the fill layers 92C may be grown on the second liner layers 92B.

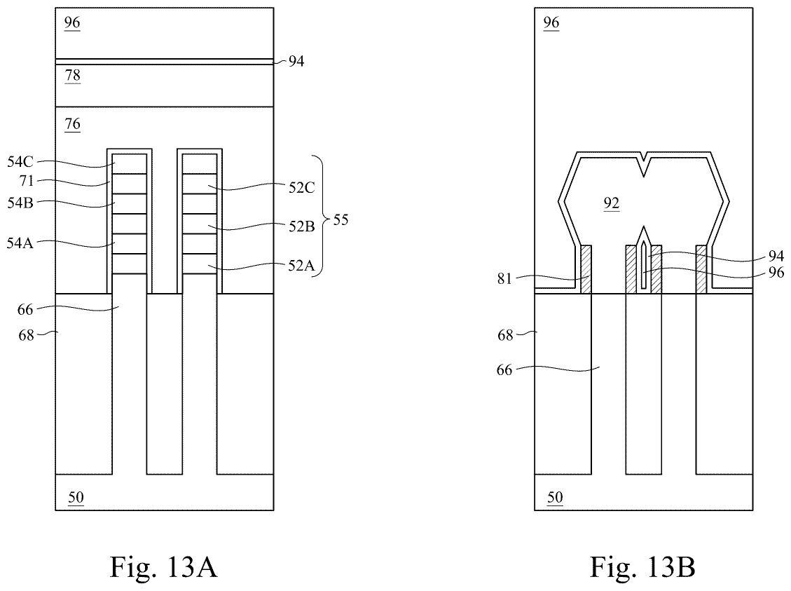

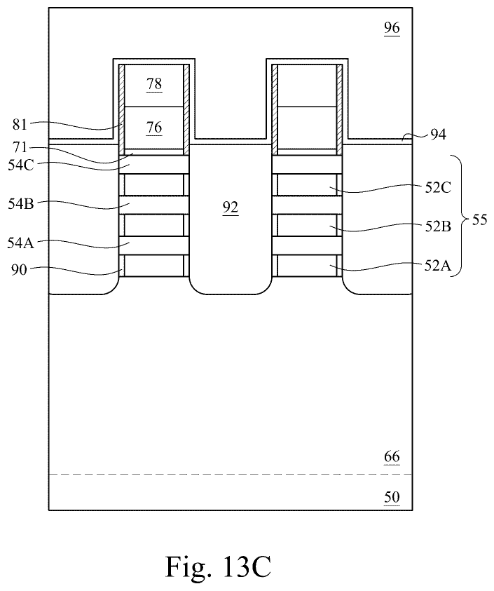

In FIGS. 13A through 13C, a first interlayer dielectric (ILD) 96 is deposited over the structure illustrated in FIGS. 12A through 12C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. A contact etch stop layer (CESL) 94 may be disposed between the first ILD 96 and the epitaxial source/drain regions 92, the masks 78, and the spacers 81. The CESL 94 may comprise a dielectric material, such as, silicon nitride, silicon oxide, silicon oxynitride, or the like, having a different etch rate than the material of the first ILD 96.

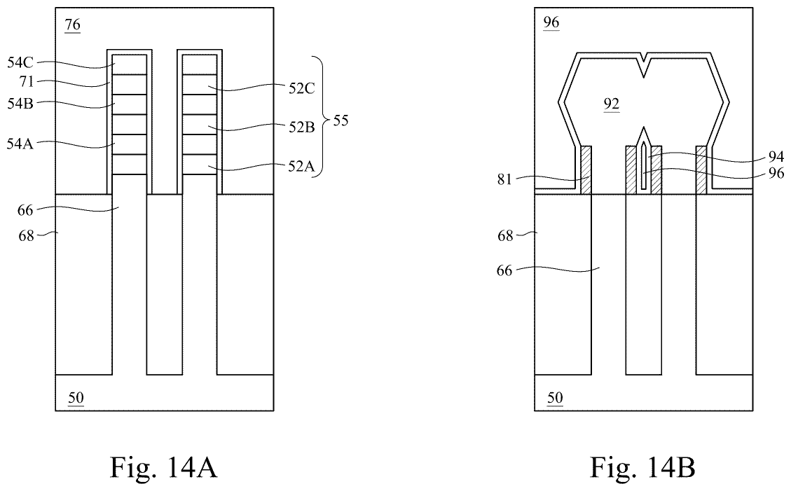

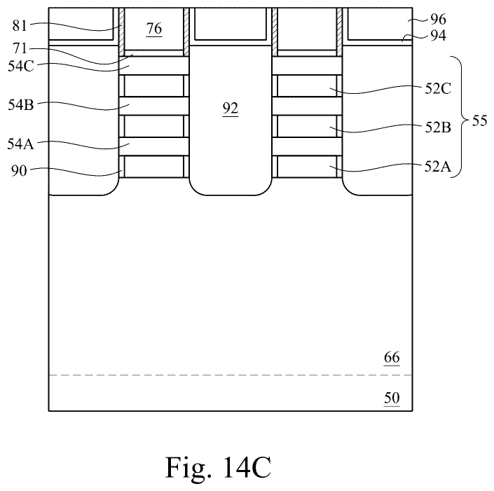

In FIGS. 14A through 14C, a planarization process, such as CMP, may be performed to level the top surfaces of the first ILD 96 and the CESL 94 with the top surfaces of the dummy gates 76 or the masks 78. The planarization process may also remove the masks 78 on the dummy gates 76, and portions of the spacers 81 along sidewalls of the masks 78. After the planarization process, top surfaces of the dummy gates 76, the spacers 81, the first ILD 96, and the CESL 94 are level within process variations. Accordingly, the top surfaces of the dummy gates 76 are exposed through the first ILD 96. In some embodiments, the masks 78 may remain, in which case the planarization process levels the top surfaces of the first ILD 96 and the CESL 94 with top surface of the masks 78 and the spacers 81.

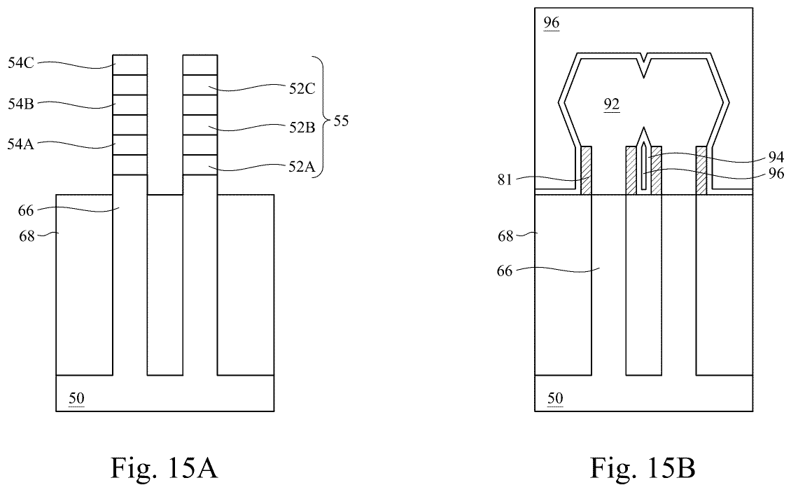

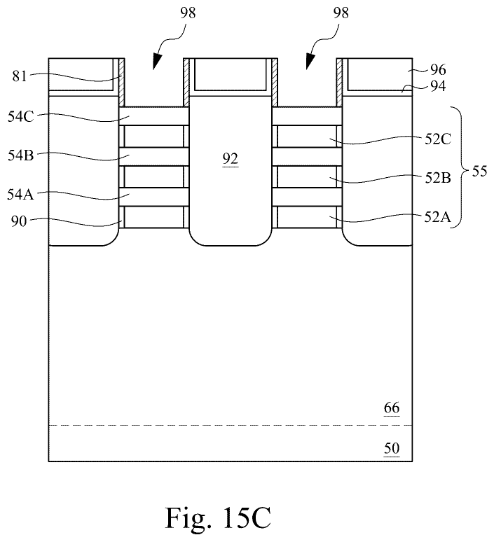

In FIGS. 15A through 15C, the dummy gates 76 and the dummy gate dielectrics 71 are removed in one or more etching processes to form third recesses 98. In some embodiments, the dummy gates 76 and the dummy gate dielectrics 71 are removed by an anisotropic dry etch process. For example, the etching processes may include dry etching processes using reaction gas(es) that selectively etch the dummy gates 76 and the dummy gate dielectrics 71 at faster rates than the first ILD 96 and/or the spacers 81. Each of the third recess 98 exposes and/or overlies portions of nanostructures 55, which act as channel regions in subsequently completed nano-FETs. Portions of the nanostructures 55, which may act as the channel regions, are disposed between neighboring pairs of the epitaxial source/drain regions 92. During the etching processes, the dummy gate dielectrics 71 may be used as etch stop layers when the dummy gates 76 are removed and may be removed after the removal of the dummy gates 76.

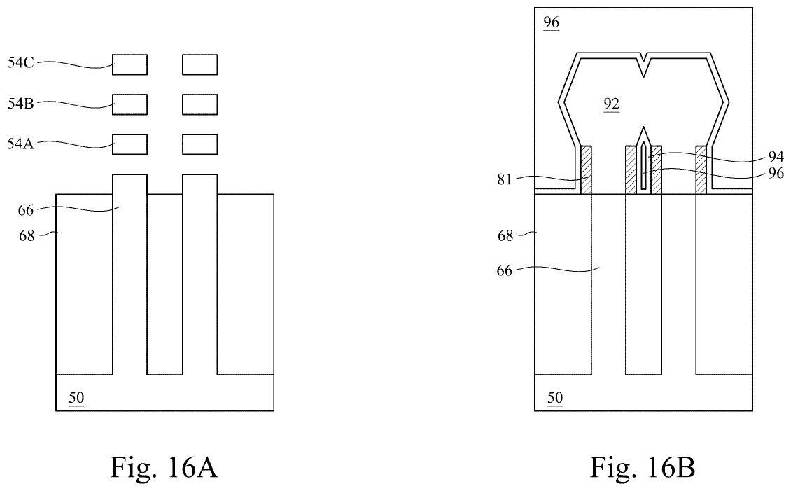

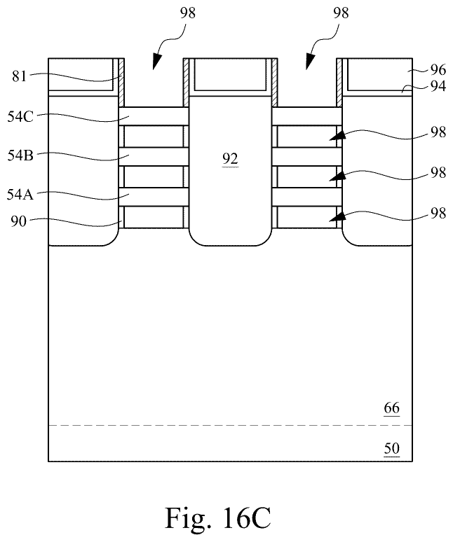

In FIGS. 16A through 16C, the first nanostructures 52 may are removed, which extends the third recesses 98. Removing the first nanostructures 52 may include using a suitable etching process, such as an isotropic etch process. The etching process may selectively remove the material of the first nanostructures 52 without significantly removing materials of the second nanostructures 54, the fins 66, or the inner spacers 90. In the embodiments in which the first nanostructures 52 comprise silicon germanium and the second nanostructures 54 include silicon, an etching process with tetramethylammonium hydroxide (TMAH), ammonium hydroxide (NH₄OH), or the like are used to remove the first nanostructures 52.

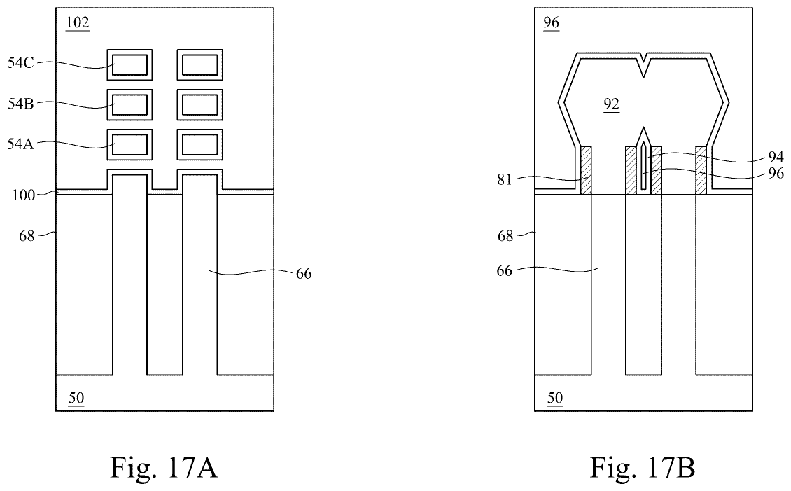

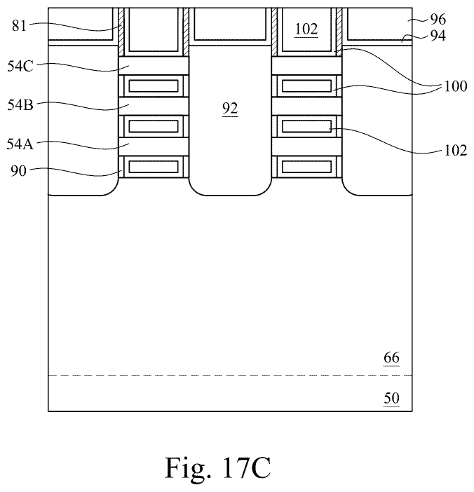

In FIGS. 17A through 17C, gate dielectric layers 100 and gate electrodes 102 are formed in the third recesses 98. The gate dielectric layers 100 may be deposited conformally in the third recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the spacers 81, and the STI regions 68 as well as on sidewalls of the spacers 81 and the inner spacers 90.

In some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a dielectric constant (k) value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, or the like.

The gate electrodes 102 are deposited over the gate dielectric layers 100, respectively, and fill the remaining portions of the third recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17C, the gate electrodes 102 may comprise any number of liner layers, any number of work function tuning layers, and a fill material. Any combination of the layers which make up the gate electrodes 102 may be deposited between adjacent ones of the second nanostructures 54 and between the second nanostructure 54A and the substrate 50.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the third recesses 98, a planarization process, such as CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as gate structures.

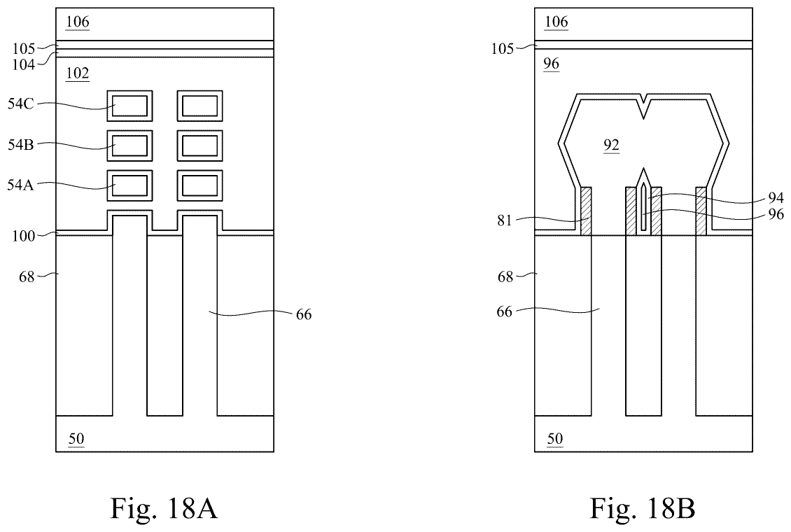

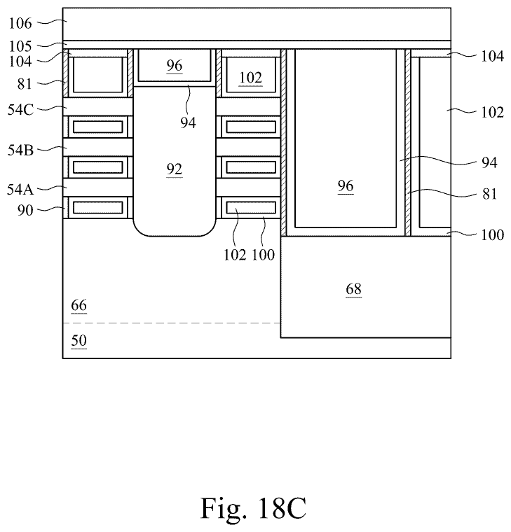

In FIGS. 18A through 18C, the gate structures (including the gate dielectric layers 100 and the corresponding overlying gate electrodes 102) are recessed, gate masks 104 are formed in the recesses, and a second ILD 106 is formed over the first ILD 96 and the gate masks 104. FIG. 18C and subsequent Figures along the same cross-section C-C′ show a region of the structure over the substrate 50 that includes an interface between the fin 66 and the STI region 68. The recesses may be formed directly over the gate structures and between opposing portions of spacers 81. Gate masks 104 may comprise one or more layers of dielectric material, such as silicon nitride, silicon oxynitride, or the like. A planarization process may be performed to remove excess material of the gate masks 104. The second ILD 106 may be formed of a dielectric material, such as PSG, BSG, BPSG, USG, or the like, and may be deposited by any suitable method, such as CVD, PECVD, FCVD, or the like. A CESL 105 may be disposed before the second ILD 106 is deposited. The CESL 105 may comprise a dielectric material, such as, silicon nitride, silicon oxide, silicon oxynitride, or the like, having a different etch rate than the material of the second ILD 106.

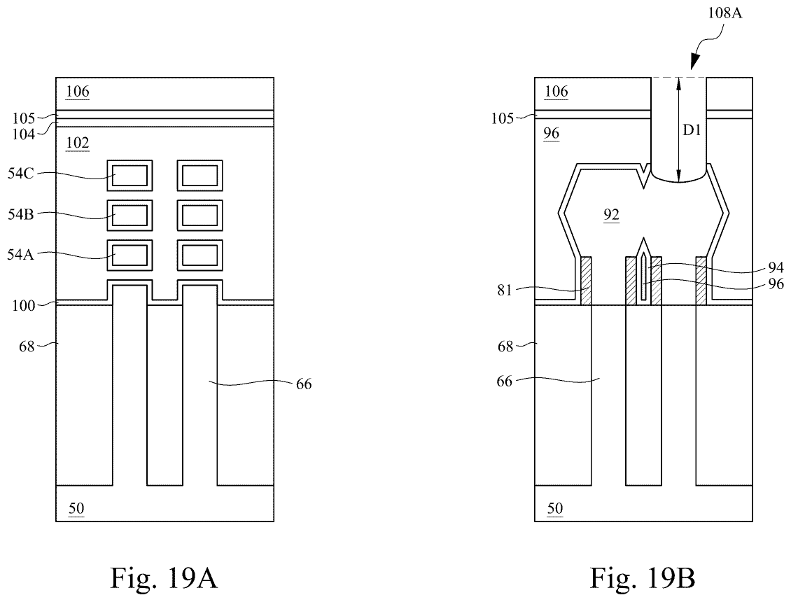

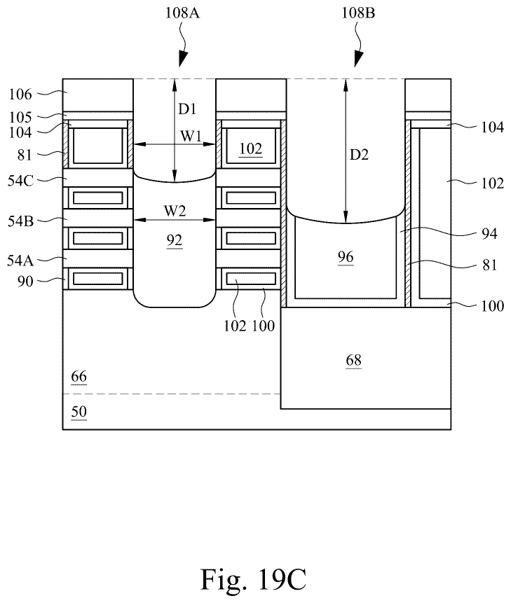

In FIGS. 19A through 19C, openings 108 are formed. The openings 108 may comprise openings 108A, which may be formed through the second ILD 106, the CESL 105, the first ILD 96, and the CESL 94 to expose the epitaxial source/drain regions 92, as shown in FIGS. 19B and 19C. FIG. 19B shows the embodiments where the opening 108A exposes one of the merged epitaxial source/drain regions 92. In other embodiments, the opening 108A exposes both of the merged epitaxial source/drain regions 92. The openings 108 may comprise openings 108B, which may be formed through the second ILD 106 and the CESL 105 to expose the first ILD 96 and the CESL 94. In the openings 108A, top portions of the epitaxial source/drain regions 92 adjacent the spacers 81 may be removed by the etching processes, which may reduce parasitic capacitance between subsequently formed the source/drain contacts over the epitaxial source/drain regions 92 and the adjacent gate structures as discussed below in greater detail below. After the etching processes, the epitaxial source/drain regions 92 may have concave top surfaces below the top surfaces of the second nanostructures 54C.

As shown in FIG. 19C, the first ILD 96 and the CESL 94 over the epitaxial source/drain region 92 may be completely removed, and the opening 108A may be free of the first ILD 96 and the CESL 94. The sidewalls of the spacers 81 may be completely exposed and the spacers 81 may be completely separated from the epitaxial source/drain region 92. The opening 108A may have a width W1, which may be a distance between the sidewalls of the spacers 81 on opposing sides of the opening 108A. The epitaxial source/drain region 92 may have a width W2, which may be a distance between sidewalls of the inner spacers 90 on opposing sides of the epitaxial source/drain region 92. The width W1 may be same as the width W2. In the openings 108B, upper portions of the first ILD 96 and the CESL 94 may be completely removed by the etching processes. After the etching processes, the first ILD 96 may have a concave top surface and the sidewalls of the spacers 81 may be partially exposed. The openings 108A may have a depth D1 and the openings 108B may have a depth D2. The depth D2 may be greater than the depth D1, which may be due to etching selectivity during the etching processes.

The openings 108 may be formed by a series of suitable etching processes, such as anisotropic drying etching processes, such as RIE, NBE, or the like, using fluorine-based etchants or the like. A hard mask (not shown) may be formed on the second ILD 106 and a pattern of the hard mask may be used to define the openings 108 during the etching processes. In some embodiments, openings in the hard mask may have same widths as the openings 108. In some embodiments, the openings in the hard mask may have smaller widths than the openings 108. The hard mask may be removed after the etching processes.

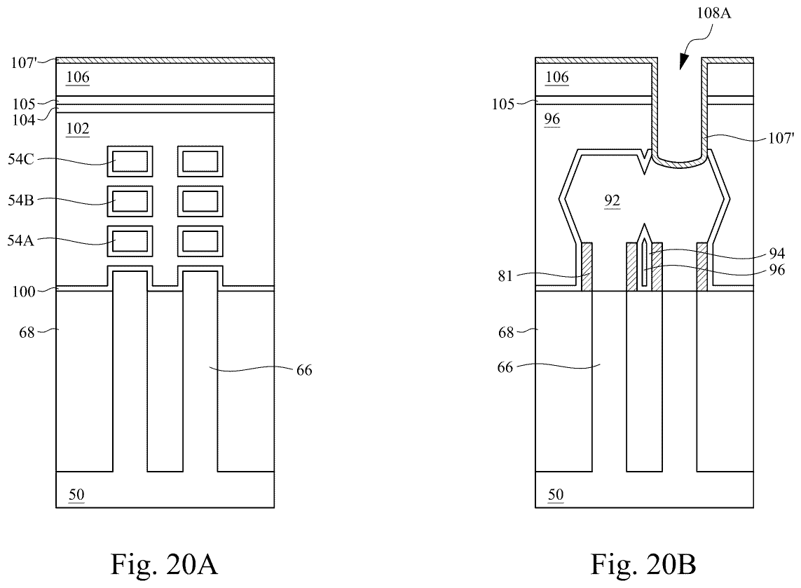

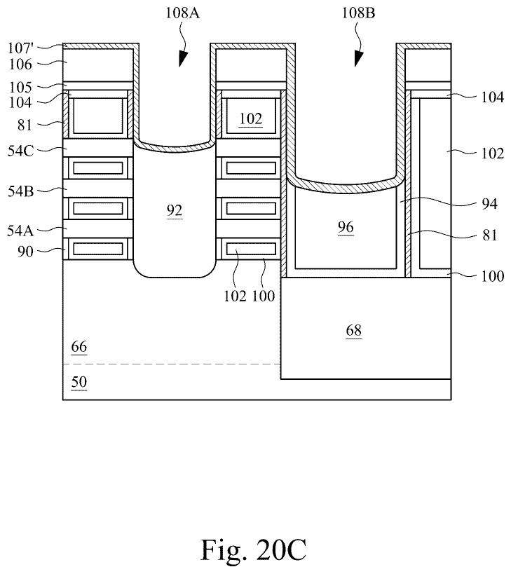

In FIGS. 20A through 20C, a dielectric liner layer 107′ is formed over the structure shown in FIGS. 19A through 19C. The dielectric liner layer 107′ may be formed on a top surface of the second ILD 106, and surfaces exposed by the openings 108, including the sidewalls of the second ILD 106, the CESL 105, and the spacers 81, as well as the top surfaces of the epitaxial source/drain regions 92, the first ILD 96, and the CESL 94. The dielectric liner layer 107′ may comprise a material with a low dielectric constant (k), which may be referred to as a low-k material, such as silicon oxycarbide, silicon oxycarbonitride, silicon carbonitride, boron nitride, silicon nitride, aluminum oxide, aluminum nitride, aluminum oxynitride or the like. The dielectric liner layer 107′ may be formed by a suitable deposition process, such as CVD, ALD, or the like.

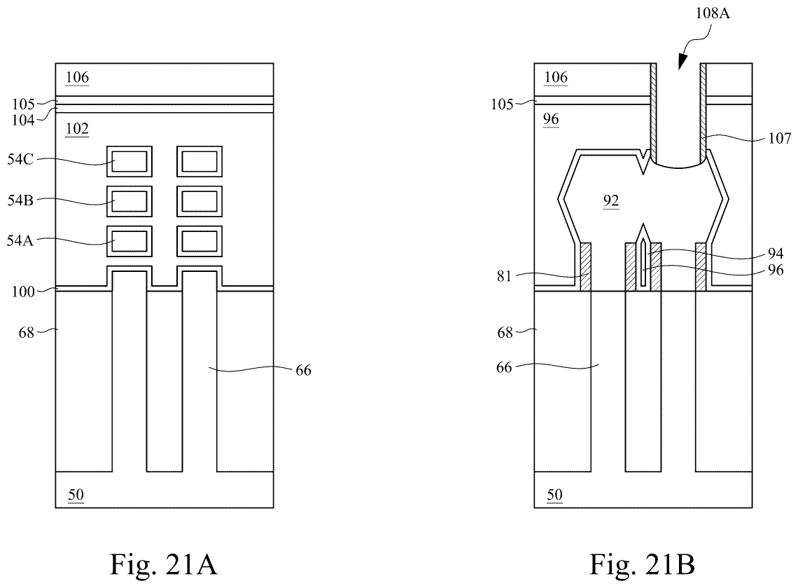

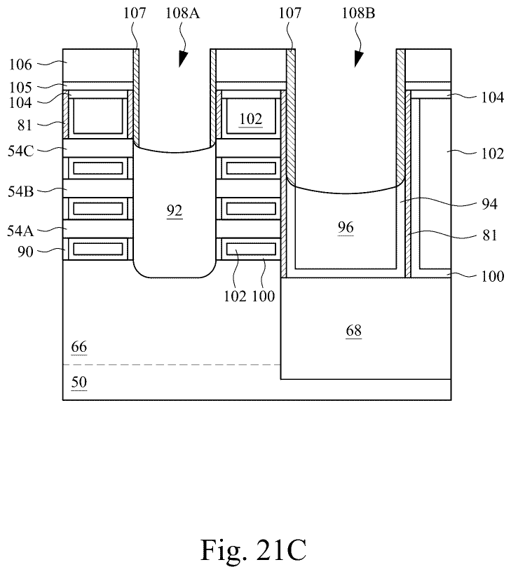

In FIGS. 21A through 21C, horizontal portions of the dielectric liner layer 107′, such as the portions of the dielectric liner layer 107′ on top surfaces of the second ILD 106, the epitaxial source/drain regions 92, and the first ILD 96, are removed. The remaining vertical portions of the dielectric liner layer 107′, such as the portions of the dielectric liner layer 107′ on the sidewalls of the second ILD 106, the CESL 105, and the spacers 81, may be referred to as the dielectric liners 107. The sidewalls of the spacers 81 may be completely covered by the dielectric liners 107. The horizontal portions of the dielectric liner layer 107′ may be removed by a suitable anisotropic drying etching process, such as RIE, NBE, or the like, using fluorine-based etchants or the like. After the etching process, the top surfaces of the epitaxial source/drain regions 92 are exposed.

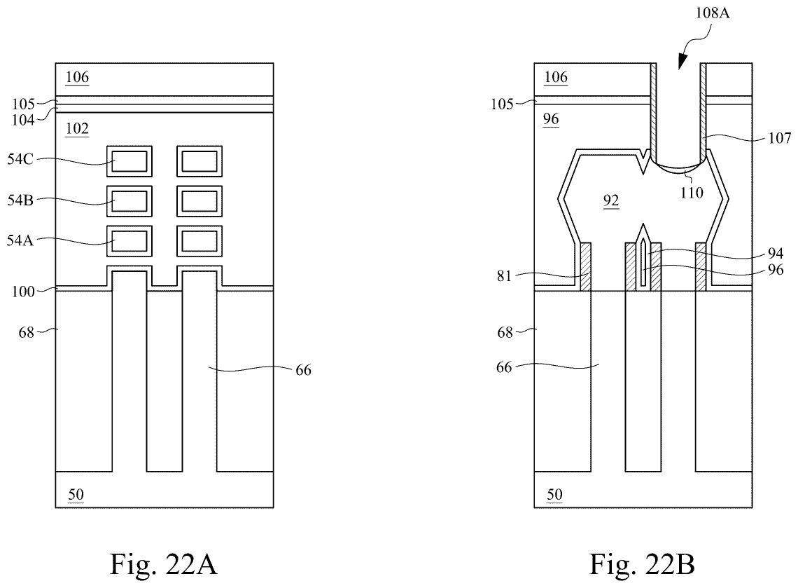

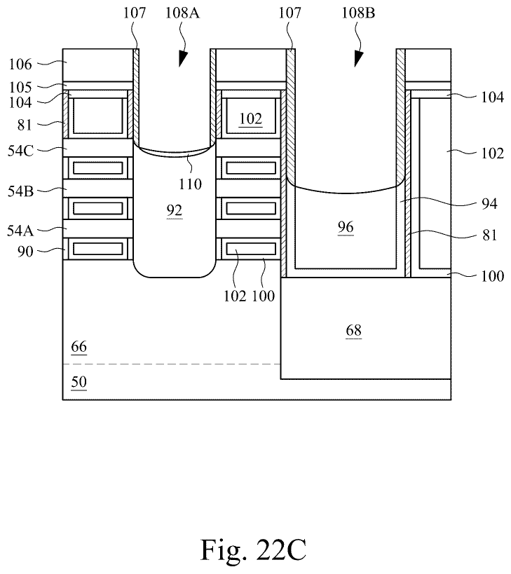

In FIGS. 22A through 22C, silicide regions 110 are formed on the top surfaces of the epitaxial source/drain regions 92. In some embodiments, the silicide regions 110 are formed by first depositing a metal layer (not shown) on the exposed top surfaces of the epitaxial source/drain regions 92, then performing a thermal annealing process. During the thermal annealing process portions of the metal layer and portions of the epitaxial source/drain regions 92 may react to form the silicide regions 110. The metal layer may comprise a metallic material capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other rare earth metals or their alloys, or the like. The un-reacted portions of the metal layer may be then removed by a suitable etching process. Although the silicide regions 110 are referred to as silicide regions, the silicide regions 110 may also be germanide regions, or silicon germanide regions (e.g., regions comprising silicide and germanide).

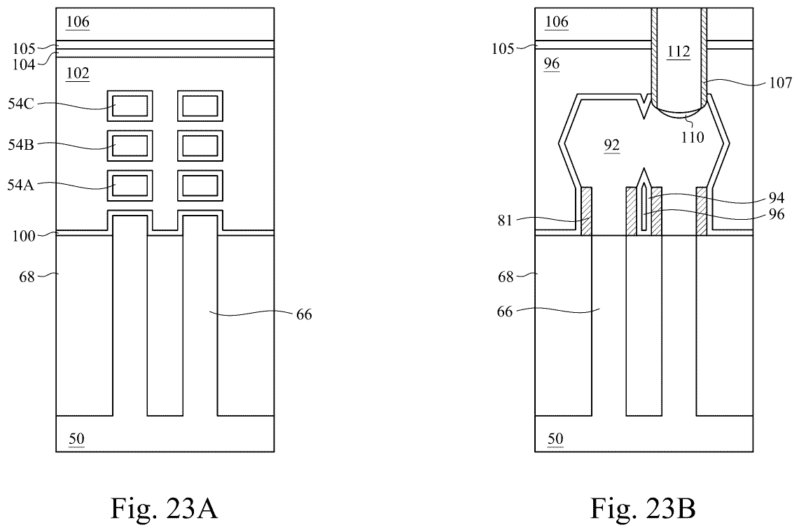

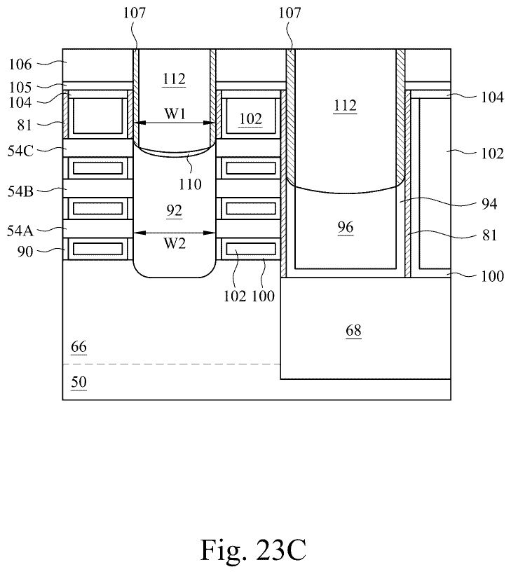

In FIGS. 23A through 23C, conductive contacts 112 are formed in the openings 108. The conductive contacts 112 formed in the openings 108A may be electrically connected to the epitaxial source/drain regions 92 by the silicide regions 110, and may be referred to as source/drain contacts. The conductive contacts 112 formed in the openings 108A may be formed on sidewalls of the dielectric liners 107 and top surfaces of the silicide regions 110. The conductive contacts 112 formed in the openings 108B may be used to establish electrical connections in directions parallel to the substrate 50. The conductive contacts 112 formed in the openings 108B may be formed on sidewalls of the dielectric liners 107 and top surfaces of the first ILD 96 and the CESL 94.

As shown in FIG. 23C, the conductive contact 112 is separated from the adjacent gate structures by the spacers 81 and the dielectric liners 107. The sidewalls of the conductive contact 112 may be completely covered by the dielectric liners 107. A combined width of the conductive contact 112 and the dielectric liners 107 on opposing sides of the conductive contact 112 may be the width W1, which may be the same as the width W2 of the epitaxial source/drain region 92. Due to the removal of the portions of the epitaxial source/drain regions 92 from the sidewalls of the spacers 81 and the addition of the dielectric liners 107, which may have a lower dielectric constant (k) than the epitaxial source/drain regions 92, on the sidewalls of the spacers 81, sufficient electrical insulation may be established between the conductive contacts 112 and the adjacent gate structures, thereby eliminating or reducing parasitic capacitance between the conductive contacts 112 and the adjacent gate structures. As a result, the performance and reliability of the subsequently formed semiconductor device may be improved.

The conductive contacts 112 may be formed of a metallic material, such as copper, copper alloy, silver, gold, tungsten, cobalt, aluminum, nickel, or the like, and formed by a suitable process, such as plating, CVD, PVD, or the like. The conductive contacts 112 may include barrier layers (not shown) on sidewalls and bottom surfaces of the conductive contacts 112. The barrier layer may be formed of titanium, titanium nitride, tantalum, tantalum nitride, or the like, and formed by a suitable process, such as CVD, PVD, or the like. A planarization process, such as CMP, may be performed to remove excess materials from the top surface of the second ILD 106. After the planarization process, top surfaces of the second ILD 106, the dielectric liners 107, and the conductive contacts 112 may be level within process variations.

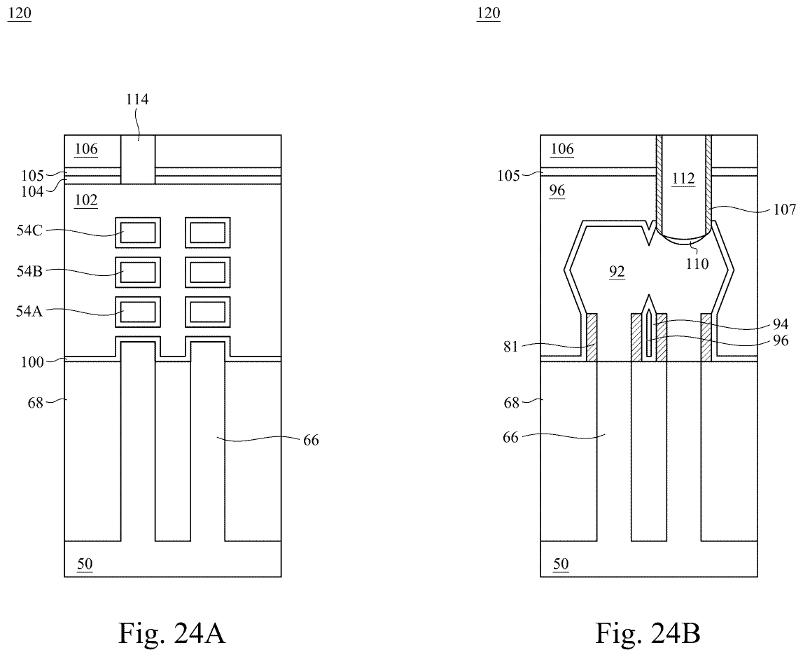

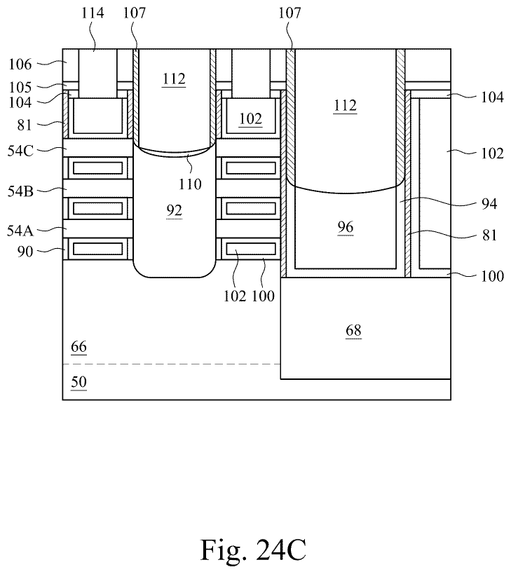

In FIGS. 24A through 24C, conductive contacts 114, which may be also referred to as gate contacts, are formed. The structure shown in FIGS. 24A through 24C may be referred to as semiconductor device 120. The conductive contacts 114 may be formed through the second ILD 106, the CESL 105, and the gate masks 104 to electrically connect to the gate electrodes 102. The conductive contacts 114 may be formed by forming openings to expose top surfaces of the gate electrodes 102, then forming a metallic material, such as copper, copper alloy, silver, gold, tungsten, cobalt, aluminum, nickel, or the like, by a suitable process, such as plating, CVD, PVD, or the like, in the openings. The conductive contacts 114 may include barrier layers (not shown) on sidewalls and bottom surfaces of the conductive contacts 114. The barrier layer may be formed of titanium, titanium nitride, tantalum, tantalum nitride, or the like, and formed by a suitable process, such as CVD, PVD, or the like. A planarization process, such as CMP, may be performed to remove excess materials from the top surfaces of the second ILD 106 and the conductive contacts 112. After the planarization process, top surfaces of the second ILD 106, the dielectric liners 107, the conductive contacts 112, and the conductive contacts 114 may be level within process variations.

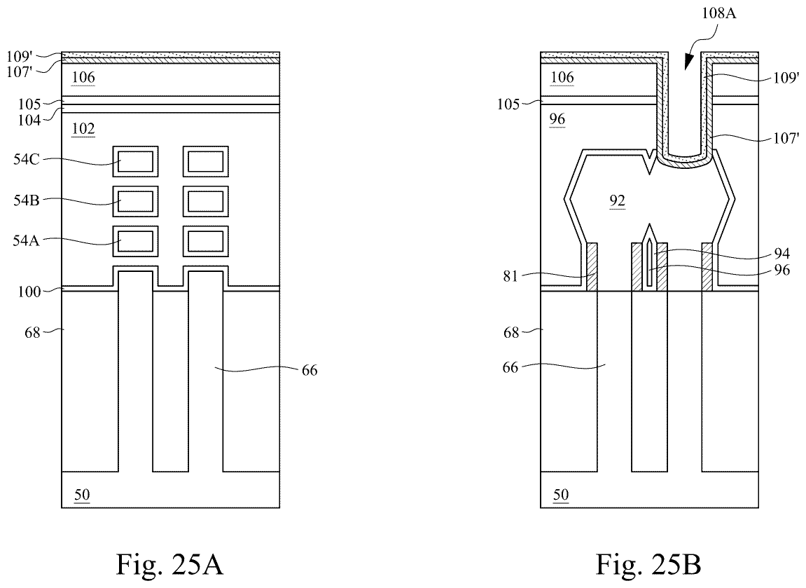

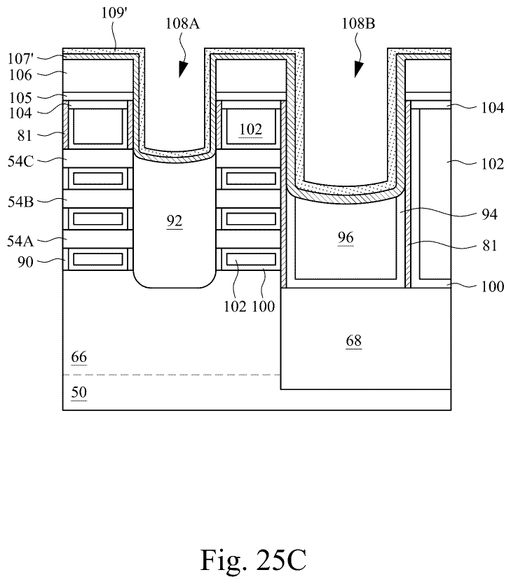

FIGS. 25A through 27C are views of intermediate processes in the manufacturing of the semiconductor device 120, in accordance with some embodiments. FIGS. 25A, 26A, and 27A illustrate cross-sectional views along the reference cross-section A-A′ illustrated in FIG. 1. FIGS. 25B, 26B, and 27B illustrate cross-sectional views along the reference cross-section B-B′ illustrated in FIG. 1. FIGS. 25C, 26C, and 27C illustrate cross-sectional views along the reference cross-section C-C′ illustrated in FIG. 1.

The structures shown in FIGS. 25A through 25C are based on the structure shown in FIGS. 20A through 20C, wherein like numerals refer to like features formed by like processes. In FIGS. 25A through 25C, a dielectric liner layer 109′ is formed over the dielectric liner layer 107′. The dielectric liner layer 109′ may comprise silicon oxycarbide, silicon oxycarbonitride, silicon carbonitride, boron nitride, silicon nitride, aluminum oxide, aluminum nitride, aluminum oxynitride, or the like. The dielectric liner layer 109′ and the dielectric liner layer 107′ may comprise different materials. The dielectric liner layer 109′ may be formed by a suitable deposition process, such as CVD, ALD, or the like.

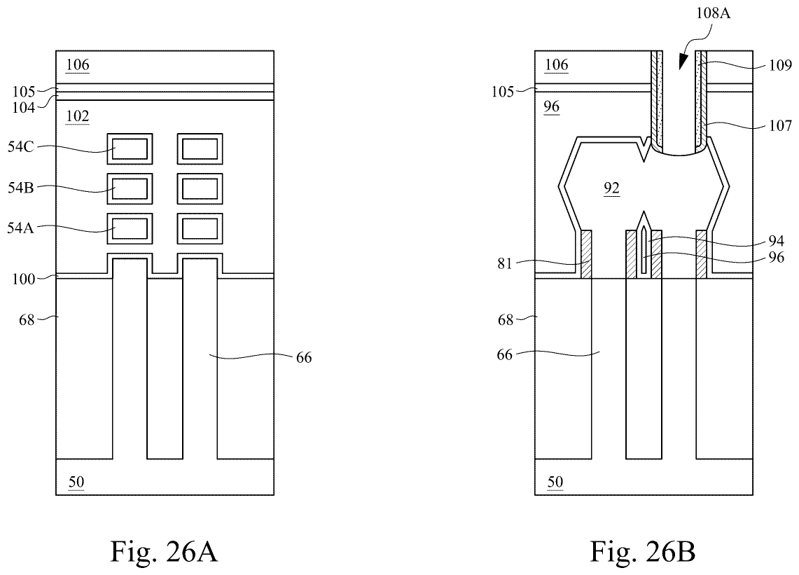

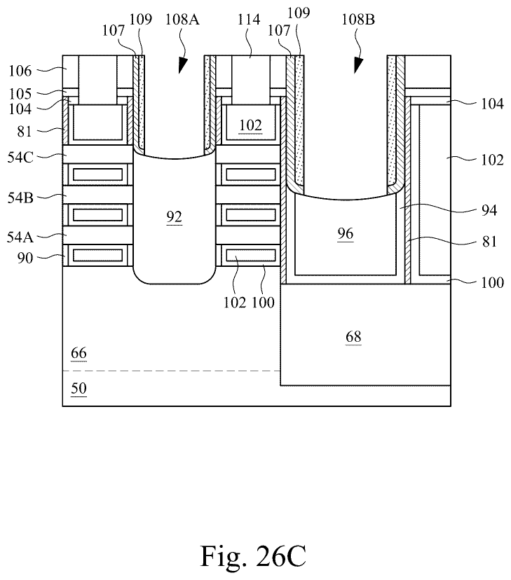

In FIGS. 26A through 26C, horizontal portions of the dielectric liner layer 107′ and the dielectric liner layer 109′, such as the portions of the dielectric liner layer 107′ and the dielectric liner layer 109′ on top surfaces of the second ILD 106, the epitaxial source/drain regions 92, and the first ILD 96 are removed. The remaining vertical portions of the dielectric liner layer 107′ and the dielectric liner layer 109′, such as the portions of the dielectric liner layer 107′ and the dielectric liner layer 109′ on the sidewalls of the second ILD 106, the CESL 105, and the spacers 81, may be referred to as the dielectric liners 107 and the dielectric liners 109. The horizontal portions of the dielectric liner layer 107′ and the dielectric liner layer 109′ may be removed by a series of suitable anisotropic drying etching processes, such as RIE, NBE, or the like, using fluorine-based etchants or the like. After the etching processes, the top surfaces of the epitaxial source/drain regions 92 are exposed.

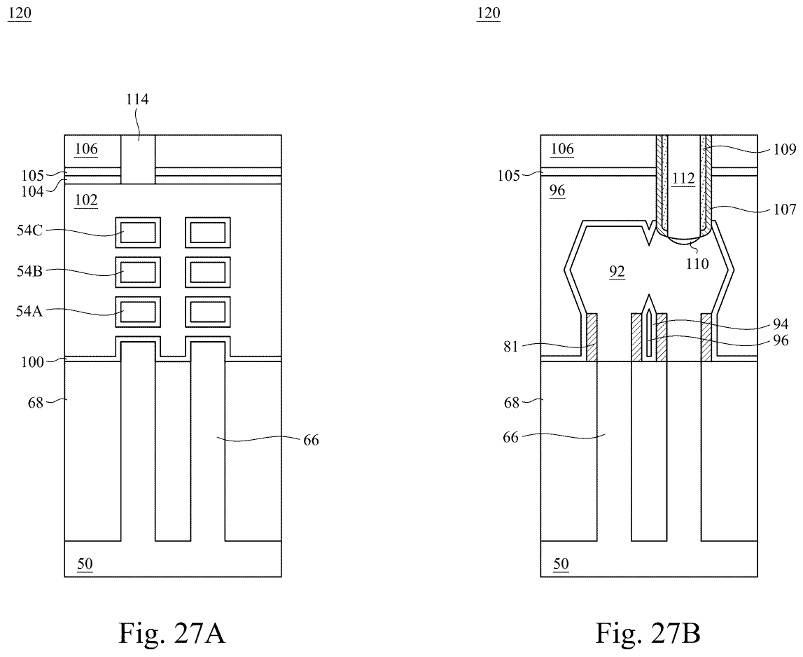

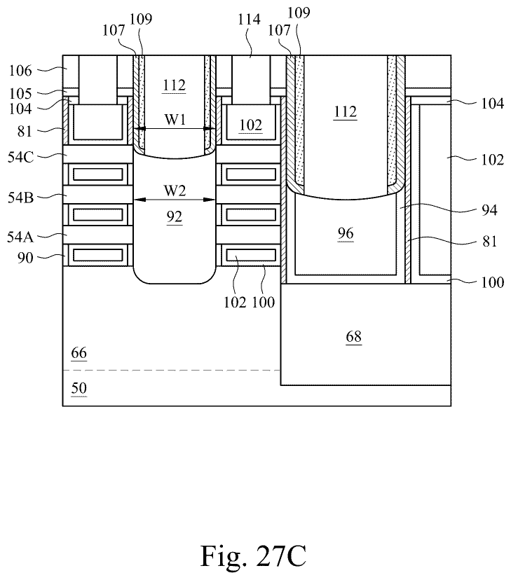

FIGS. 27A through 27C show a semiconductor device 120 in accordance with some embodiments. The semiconductor device 120 may be obtained after processes described with respect to FIG. 22A through 24C are performed on the structure shown in FIGS. 26A through 26C, wherein like numerals refer to like features formed by like processes. The conductive contacts 112 formed in the openings 108A may be formed on the sidewalls of the dielectric liners 107 and the dielectric liners 109, and the top surfaces of the silicide regions 110. The conductive contacts 112 formed in the openings 108B may be formed on the sidewalls of the dielectric liners 107 and the dielectric liners 109, and the top surfaces of the first ILD 96 and the CESL 94.

As shown in FIG. 27C, the conductive contact 112 is separated from the adjacent gate structures by the spacers 81, the dielectric liners 107, and the dielectric liners 109. A combined width of the conductive contact 112 as well as the dielectric liners 107 and the dielectric liners 109 on opposing sides of the conductive contact 112 may be the width W1, which may be the same as the width W2 of the epitaxial source/drain region 92. Due to the removal of the portions of the epitaxial source/drain regions 92 from the sidewalls of the spacers 81 and the addition of the dielectric liners 107 and the dielectric liners 109, which may have lower dielectric constants (k) than the epitaxial source/drain regions 92, on the sidewalls of the spacers 81, sufficient electrical insulation may be established between the conductive contacts 112 and the adjacent gate structures, thereby eliminating or reducing parasitic capacitance between the conductive contacts 112 and the adjacent gate structures. As a result, the performance and reliability of the semiconductor device 120 may be improved.

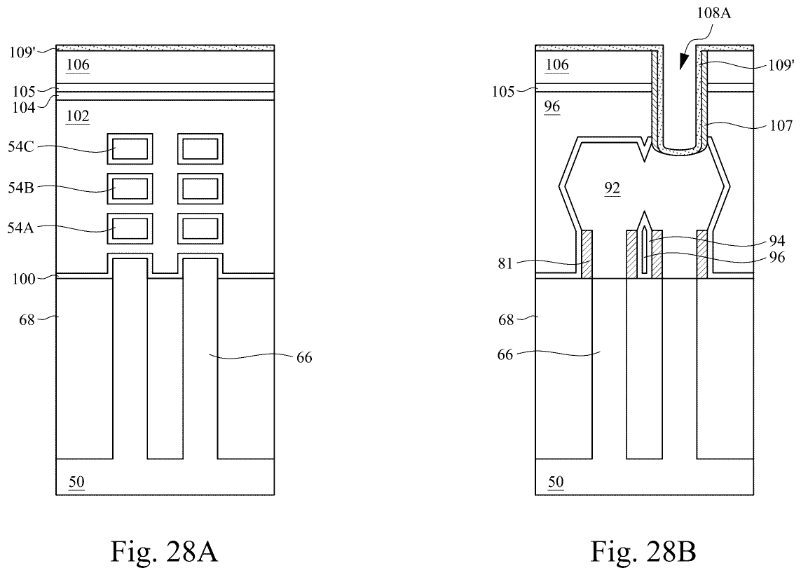

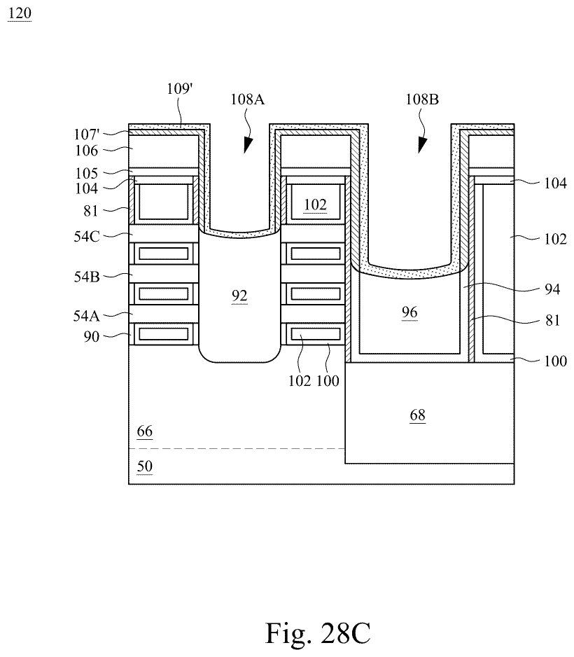

FIGS. 28A through 30C are views of intermediate processes in the manufacturing of the semiconductor device 120, in accordance with some embodiments. FIGS. 28A, 29A, and 30A illustrate cross-sectional views along the reference cross-section A-A′ illustrated in FIG. 1. FIGS. 28B, 29B, and 30B illustrate cross-sectional views along the reference cross-section B-B′ illustrated in FIG. 1. FIGS. 28C, 29C, and 30C illustrate cross-sectional views along the reference cross-section C-C′ illustrated in FIG. 1.

The structures shown in FIGS. 28A through 30C are based on the structure shown in FIGS. 21A through 21C, wherein like numerals refer to like features formed by like processes. In FIGS. 28A through 28C, a dielectric liner layer 109′ is formed over the top surfaces of the second ILD 106, the first ILD 96, and epitaxial source/drain regions 92, as well as the sidewalls of the dielectric liners 107. The dielectric liner layer 109′ may comprise silicon nitride, aluminum oxide, aluminum nitride, aluminum oxynitride, or the like. The dielectric liner layer 109′ and the dielectric liners 107 may comprise different materials. The dielectric liner layer 109′ may be formed by a suitable deposition process, such as CVD, ALD, or the like.

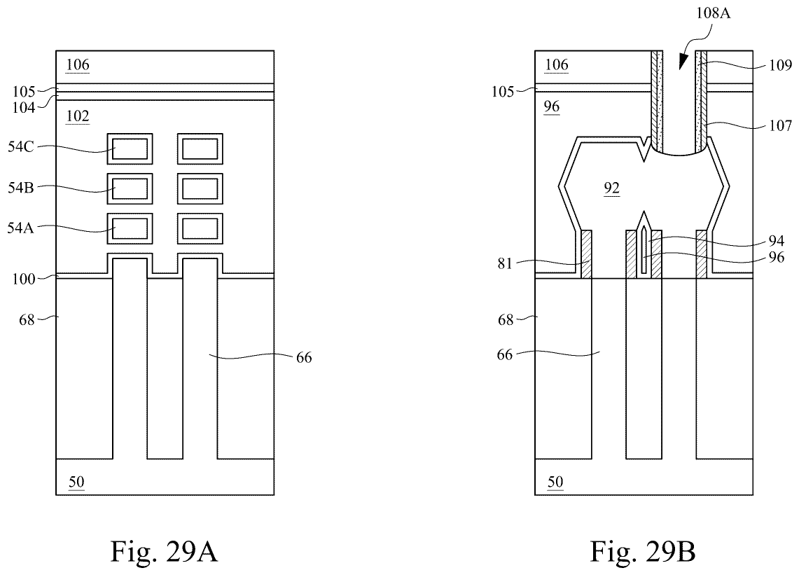

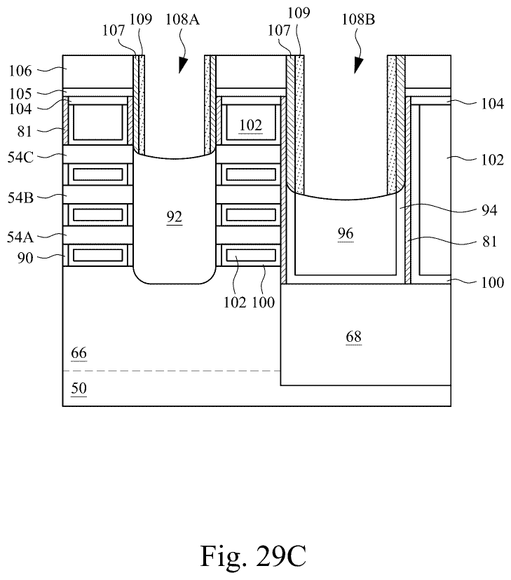

In FIGS. 29A through 29C, horizontal portions of the dielectric liner layer 109′, such as the portions of the dielectric liner layer 109′ on top surfaces of the second ILD 106, the epitaxial source/drain regions 92, and the first ILD 96 are removed. The remaining vertical portions of the dielectric liner layer 109′ on the sidewalls of the dielectric liners 107, may be referred to as the dielectric liners 109. The horizontal portions of the dielectric liner layer 109′ may be removed by a suitable anisotropic drying etching processes, such as RIE, NBE, or the like, using fluorine-based etchants or the like. After the etching process, the top surfaces of the epitaxial source/drain regions 92 are exposed.

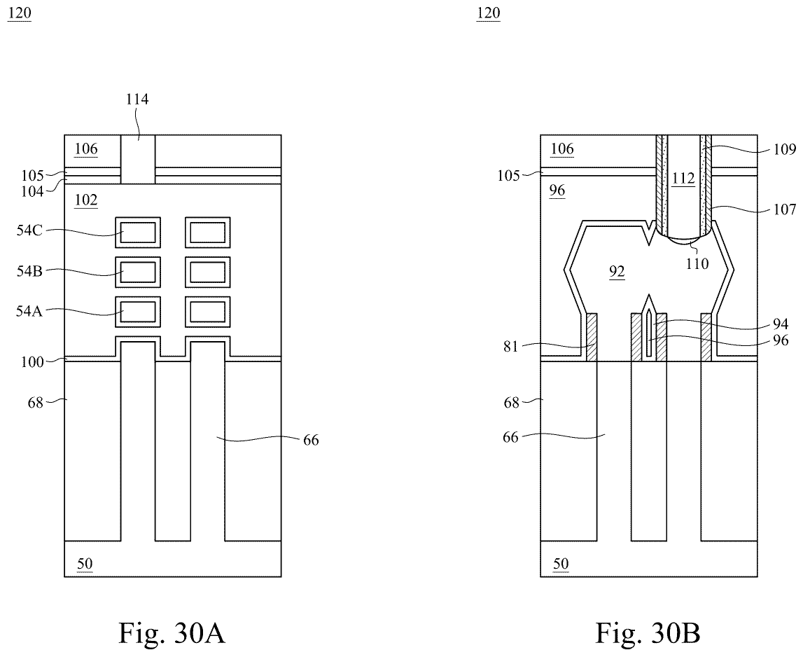

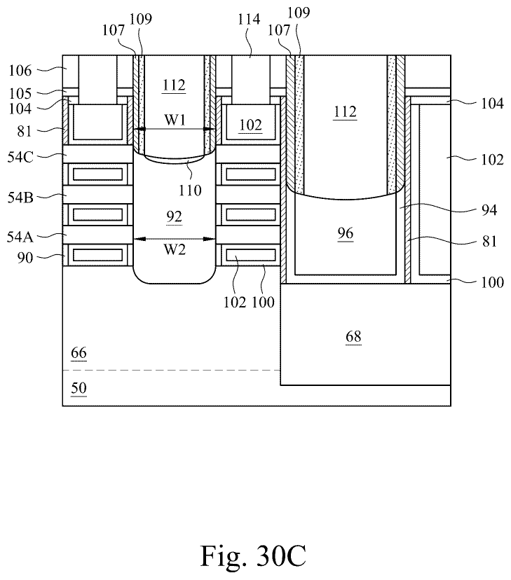

FIGS. 30A through 30C show a semiconductor device 120 in accordance with some embodiments. The semiconductor device 120 may be obtained after processes described with respect to FIG. 22A through 24C are performed on the structure shown in FIGS. 29A through 29C, wherein like numerals refer to like features formed by like processes. The conductive contacts 112 formed in the openings 108A may be formed on the sidewalls of the dielectric liners 109, and the top surfaces of the silicide regions 110. The conductive contacts 112 formed in the openings 108B may be formed on the sidewalls of the dielectric liners 109, and the top surfaces of the first ILD 96 and the CESL 94. The conductive contacts 112 may be separated from the dielectric liners 107 by the dielectric liners 109.

As shown in FIG. 30C, the conductive contact 112 is separated from the adjacent gate structures by the spacers 81, the dielectric liners 107, and the dielectric liners 109. The combined width of the conductive contact 112 as well as the dielectric liners 107 and the dielectric liners 109 on opposing sides of the conductive contact 112 may be the width W1, which may be the same as the width W2 of the epitaxial source/drain region 92. Due to the removal of the portions of the epitaxial source/drain regions 92 from the sidewalls of the spacers 81 and the addition of the dielectric liners 107 and the dielectric liners 109, which may have lower dielectric constants (k) than the epitaxial source/drain regions 92, on the sidewalls of the spacers 81, sufficient electrical insulation may be established between the conductive contacts 112 and the adjacent gate structures, thereby eliminating or reducing parasitic capacitance between the conductive contacts 112 and the adjacent gate structures. As a result, the performance and reliability of the semiconductor device 120 may be improved.

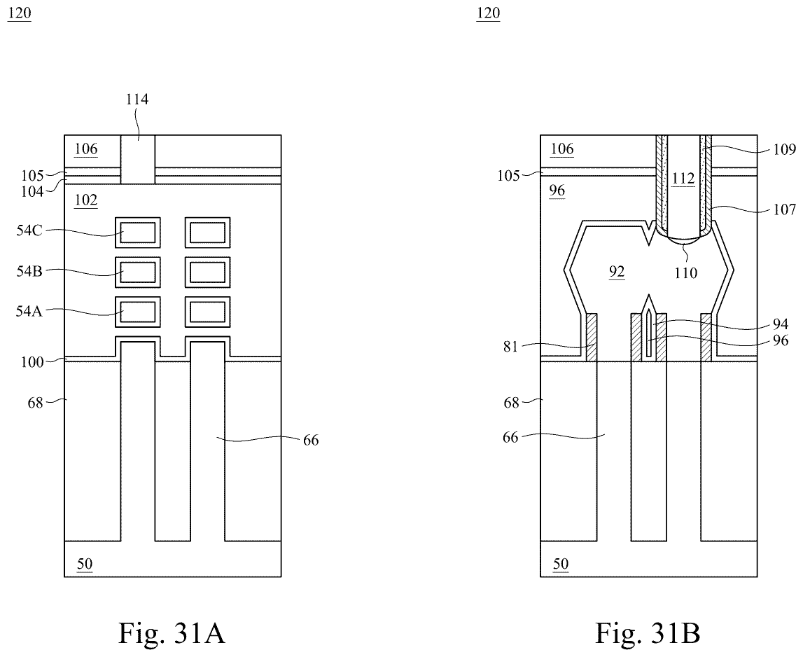

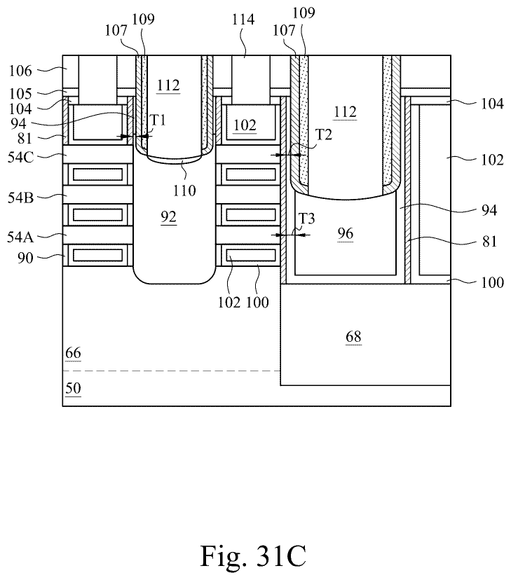

FIGS. 31A through 31C are views of the semiconductor device 120, in accordance with some embodiments, similar to the embodiments shown in FIGS. 27A through 27C, wherein like numerals refer to like features formed by like processes. As shown in FIG. 31C, the portions of the CESL 94 and the epitaxial source/drain regions 92 on the sidewalls of the spacers 81 may be partially removed. As a result, remaining portions of the CESL 94 and the epitaxial source/drain regions 92 are between the spacers 81 and the dielectric liners 107. Remaining portions of the epitaxial source/drain regions 92 between the spacers 81 and the dielectric liners 107 may have a thickness T1, which may lead to sufficient electrical insulation between the conductive contacts 112 and the adjacent gate structures, thereby eliminating or reducing parasitic capacitance between the conductive contacts 112 and the adjacent gate structures. As a result, the performance and reliability of the semiconductor device 120 may be improved.

As shown in FIG. 31C, upper portions of the CESL 94 may be partially removed. As a result, the upper portions of the CESL 94 is between the spacers 81 and the dielectric liners 107. The upper portions of the CESL 94 may have a thickness T2 after the partial removal and lower portions of the CESL 94 may have a thickness T3. The thickness T3 may be larger than the thickness T2. FIGS. 31A through 31C illustrate embodiments with the configurations of the dielectric liners 107 and the dielectric liners 109 similar to the embodiments shown in FIGS. 27A through 27C as an example. In other embodiments, the configurations of the dielectric liners 107 and the dielectric liners 109 are similar to the embodiments shown in FIGS. 30A through 30C. In further other embodiments, the dielectric liners 109 are omitted and the configurations of the dielectric liners 107 are similar to the embodiments shown in FIGS. 24A through 24C.

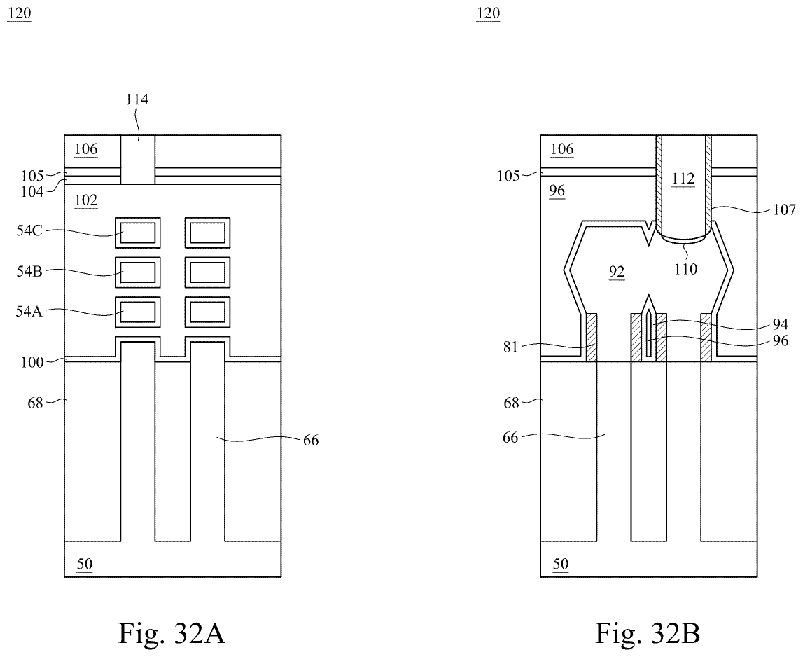

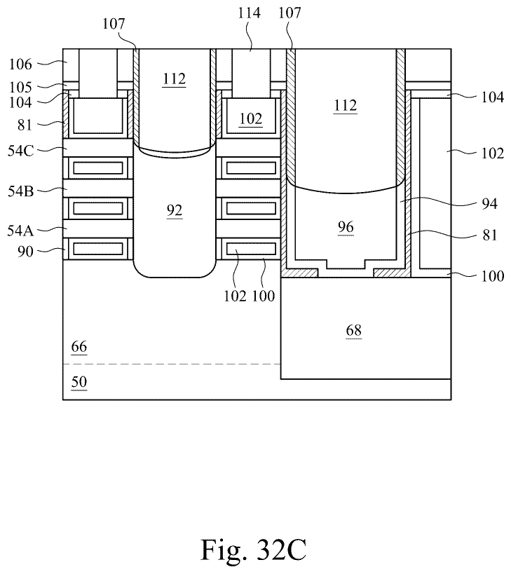

FIGS. 32A through 32C are views of the semiconductor device 120, in accordance with some embodiments, similar to the embodiments shown in FIGS. 24A through 24C, wherein like numerals refer to like features formed by like processes. As shown in FIG. 31C, the spacers 81 over the STI region 68 may have a shape of an “L” with vertical portions on the top surface of the STI region 68.

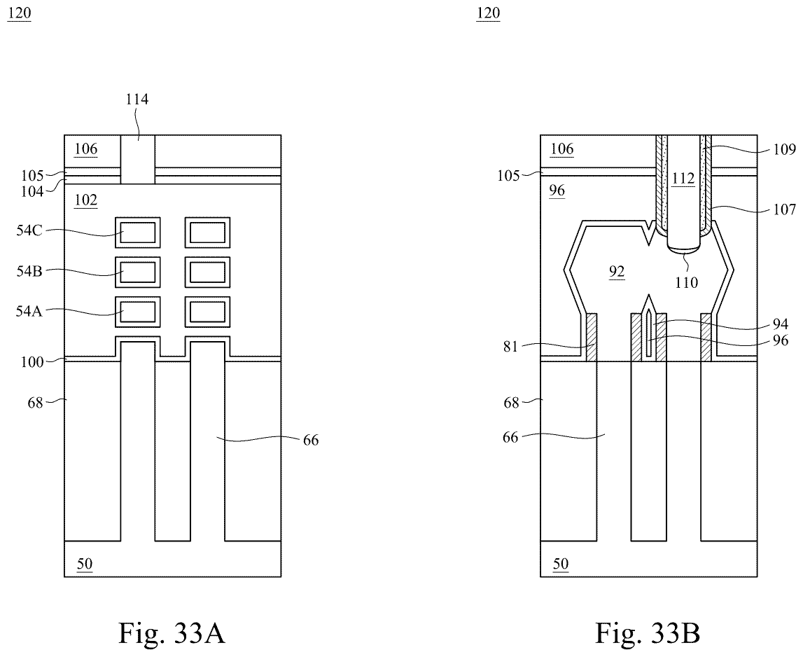

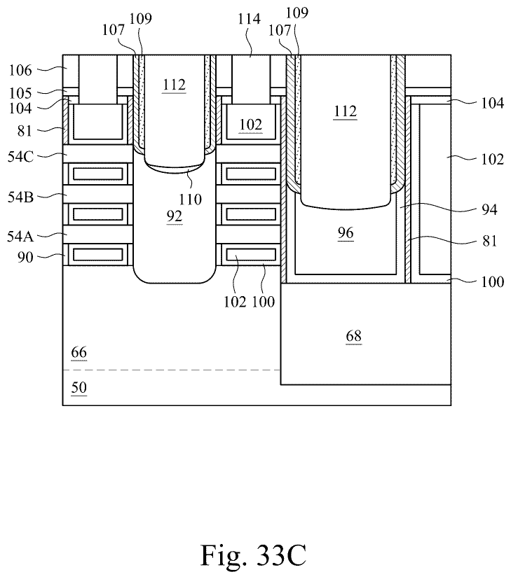

FIGS. 33A through 33C are views of the semiconductor device 120, in accordance with some embodiments, similar to the embodiments shown in FIGS. 27A through 27C, wherein like numerals refer to like features formed by like processes. As shown in FIGS. 33B and 33C, bottom surfaces of the conductive contacts 112 may extend beyond bottom surfaces of the dielectric liners 109 into the epitaxial source/drain region 92 and the first ILD 96.

The embodiments of the present disclosure have some advantageous features. By at least partially removing of the portions of the epitaxial source/drain regions 92 from the sidewalls of the spacers 81 and adding the dielectric liners 107 and optionally the dielectric liners 109, on the sidewalls of the spacers 81, sufficient electrical insulation may be established between the conductive contacts 112 and the adjacent gate structures, thereby eliminating or reducing parasitic capacitance between the conductive contacts 112 and the adjacent gate structures. As a result, the performance and reliability of the semiconductor device 120 may be improved.

In an embodiment, a semiconductor device includes a source/drain region; a first nanostructure along a sidewall of the source/drain region; a gate structure wrapping around the first nanostructure; a first gate spacer along a sidewall of a first portion of the gate structure; a first dielectric layer over the source/drain region and the gate structure; a first conductive contact extending through the first dielectric layer and electrically connected to the source/drain region; and a first dielectric liner along a sidewall of the first conductive contact, wherein the first dielectric liner extends from a level of a top surface of the first conductive contact to a top surface of the source/drain region, and wherein the first dielectric liner is in contact with a sidewall of the first gate spacer. In an embodiment, the sidewall of the first gate spacer is completely covered by the first dielectric liner. In an embodiment, the first dielectric liner is in contact with the sidewall of the first conductive contact. In an embodiment, the semiconductor device further includes a second dielectric liner between the first dielectric liner and the first conductive contact, wherein the second dielectric liner from the level of the top surface of the first conductive contact towards the source/drain region, and wherein second dielectric liner includes a different material from the first dielectric liner. In an embodiment, the first dielectric liner extends underneath the second dielectric liner and is in contact with the sidewall of the first conductive contact. In an embodiment, the second dielectric liner extends to the top surface of the source/drain region. In an embodiment, the semiconductor device further includes a semiconductor substrate underneath the first nanostructure; an isolation region over the semiconductor substrate and underneath the first dielectric layer; a second gate spacer between the isolation region and the first dielectric layer; a second conductive contact extending through the first dielectric layer; and a second dielectric liner along a sidewall of the second conductive contact, wherein the second dielectric liner extends through the first dielectric layer, and wherein the second dielectric liner is in contact with a sidewall of the second gate spacer. In an embodiment, the first dielectric liner and the second dielectric liner include a same material.

In an embodiment, a method of forming a semiconductor device includes forming a first nanostructure over a semiconductor substrate; depositing a first gate spacer over the first nanostructure; forming a first opening through the first nanostructure, wherein the first opening exposes a sidewall of the first nanostructure; growing a source/drain region in the first opening, wherein the source/drain region is on the sidewall of the first nanostructure, and wherein a first portion of the source/drain region is on a sidewall of the first gate spacer; forming a first contact etch stop layer over the source/drain region and a first dielectric layer over the first contact etch stop layer, wherein a first portion of the first contact etch stop layer is on the sidewall of the first gate spacer; forming a second opening through the first dielectric layer, wherein forming the second opening includes at least partially removing the first portion of the source/drain region and the first portion of the first contact etch stop layer on the sidewall of the first gate spacer; depositing a first dielectric liner in the second opening, wherein the first dielectric liner includes a low-k material; and forming a first conductive contact in the second opening, wherein the first conductive contact is electrically connected to the source/drain region. In an embodiment, the sidewall of the first gate spacer is exposed after forming the second opening. In an embodiment, the second opening exposes the sidewall of the first gate spacer, and wherein the first dielectric liner is formed on the sidewall of the first gate spacer. In an embodiment, the method further includes depositing a second dielectric liner in the second opening after depositing the first dielectric liner and before forming the first conductive contact, wherein the first dielectric liner and the second dielectric liner include different materials. In an embodiment, the method further includes forming an isolation region over the semiconductor substrate; depositing a second gate spacer over the isolation region, wherein a second portion of the first contact etch stop layer is on a sidewall of the second gate spacer; forming a third opening by partially removing the second portion of the first contact etch stop layer; and depositing a second dielectric liner in the third opening. In an embodiment, the third opening exposes the sidewall of the second gate spacer, and where the second dielectric liner is on the sidewall of the second gate spacer.

In an embodiment, a method of forming a semiconductor device includes forming a first nanostructure over a semiconductor substrate; depositing a first gate spacer over the first nanostructure; growing a source/drain region, wherein a first portion of the source/drain region is on a sidewall of the first gate spacer, and wherein a second portion of the source/drain region is on a sidewall of the first nanostructure; forming a first contact etch stop layer over the source/drain region, wherein a first portion of the first contact etch stop layer is on the sidewall of the first gate spacer; forming a first opening by removing the first portion of the first contact etch stop layer and the first portion of the source/drain region, wherein the first opening exposes the sidewall of the first gate spacer; depositing a first dielectric liner in the first opening and on the sidewall of the first gate spacer; and forming a first conductive contact in the first opening. In an embodiment, the first opening and the source/drain region have a same width in a cross-sectional view. In an embodiment, the first dielectric liner includes a low-k material. In an embodiment, the method further includes depositing a third dielectric liner in the first opening, wherein the third dielectric liner is between the first dielectric liner and the first conductive contact, and wherein the first dielectric liner is in contact with the first conductive contact. In an embodiment, the method further includes depositing a third dielectric liner in the first opening, wherein the third dielectric liner is between the first dielectric liner and the first conductive contact, and wherein the first dielectric liner is separated from the first conductive contact by the third dielectric liner. In an embodiment, a top surface of the source/drain region is concave after forming the first opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a source/drain region;
a first nanostructure along a sidewall of the source/drain region;
a gate structure wrapping around the first nanostructure;
a first gate spacer along a sidewall of a first portion of the gate structure;
a first dielectric layer over the source/drain region and the gate structure;
a first conductive contact extending through the first dielectric layer and electrically connected to the source/drain region; and
a first dielectric liner along a sidewall of the first conductive contact, wherein the first dielectric liner extends from a level of a top surface of the first conductive contact to a top surface of the source/drain region, and wherein the first dielectric liner is in contact with a sidewall of the first gate spacer.

2. The semiconductor device of claim 1, wherein the sidewall of the first gate spacer is completely covered by the first dielectric liner.

3. The semiconductor device of claim 1, wherein the first dielectric liner is in contact with the sidewall of the first conductive contact.

4. The semiconductor device of claim 1, further comprising a second dielectric liner between the first dielectric liner and the first conductive contact, wherein the second dielectric liner from the level of the top surface of the first conductive contact towards the source/drain region, and wherein second dielectric liner comprises a different material from the first dielectric liner.

5. The semiconductor device of claim 4, wherein the first dielectric liner extends underneath the second dielectric liner and is in contact with the sidewall of the first conductive contact.

6. The semiconductor device of claim 4, wherein the second dielectric liner extends to the top surface of the source/drain region.

7. The semiconductor device of claim 1, further comprising:
a semiconductor substrate underneath the first nanostructure;
an isolation region over the semiconductor substrate and underneath the first dielectric layer;
a second gate spacer between the isolation region and the first dielectric layer;
a second conductive contact extending through the first dielectric layer; and
a second dielectric liner along a sidewall of the second conductive contact, wherein the second dielectric liner extends through the first dielectric layer, and wherein the second dielectric liner is in contact with a sidewall of the second gate spacer.

8. The semiconductor device of claim 7, wherein the first dielectric liner and the second dielectric liner comprise a same material.

9. A method of forming a semiconductor device, the method comprising:
forming a first nanostructure over a semiconductor substrate;
depositing a first gate spacer over the first nanostructure;
forming a first opening through the first nanostructure, wherein the first opening exposes a sidewall of the first nanostructure;
growing a source/drain region in the first opening, wherein the source/drain region is on the sidewall of the first nanostructure, and wherein a first portion of the source/drain region is on a sidewall of the first gate spacer;
forming a first contact etch stop layer over the source/drain region and a first dielectric layer over the first contact etch stop layer, wherein a first portion of the first contact etch stop layer is on the sidewall of the first gate spacer;
forming a second opening through the first dielectric layer, wherein forming the second opening comprises at least partially removing the first portion of the source/drain region and the first portion of the first contact etch stop layer on the sidewall of the first gate spacer;
depositing a first dielectric liner in the second opening, wherein the first dielectric liner comprises a low-k material; and
forming a first conductive contact in the second opening, wherein the first conductive contact is electrically connected to the source/drain region.

10. The method of claim 9, wherein the sidewall of the first gate spacer is exposed after forming the second opening.

11. The method of claim 9, wherein the second opening exposes the sidewall of the first gate spacer, and wherein the first dielectric liner is formed on the sidewall of the first gate spacer.

12. The method of claim 9, further comprising depositing a second dielectric liner in the second opening after depositing the first dielectric liner and before forming the first conductive contact, wherein the first dielectric liner and the second dielectric liner comprise different materials.

13. The method of claim 9, further comprising:
forming an isolation region over the semiconductor substrate;
depositing a second gate spacer over the isolation region, wherein a second portion of the first contact etch stop layer is on a sidewall of the second gate spacer;
forming a third opening by partially removing the second portion of the first contact etch stop layer; and
depositing a second dielectric liner in the third opening.

14. The method of claim 13, wherein the third opening exposes the sidewall of the second gate spacer, and where the second dielectric liner is on the sidewall of the second gate spacer.

15. A method of forming a semiconductor device, the method comprising:
forming a first nanostructure over a semiconductor substrate;
depositing a first gate spacer over the first nanostructure;
growing a source/drain region, wherein a first portion of the source/drain region is on a sidewall of the first gate spacer, and wherein a second portion of the source/drain region is on a sidewall of the first nanostructure;
forming a first contact etch stop layer over the source/drain region, wherein a first portion of the first contact etch stop layer is on the sidewall of the first gate spacer;
forming a first opening by removing the first portion of the first contact etch stop layer and the first portion of the source/drain region, wherein the first opening exposes the sidewall of the first gate spacer;
depositing a first dielectric liner in the first opening and on the sidewall of the first gate spacer; and
forming a first conductive contact in the first opening.

16. The method of claim 15, wherein the first opening and the source/drain region have a same width in a cross-sectional view.

17. The method of claim 16, wherein the first dielectric liner comprises a low-k material.

18. The method of claim 15, further comprising depositing a third dielectric liner in the first opening, wherein the third dielectric liner is between the first dielectric liner and the first conductive contact, and wherein the first dielectric liner is in contact with the first conductive contact.

19. The method of claim 15, further comprising depositing a third dielectric liner in the first opening, wherein the third dielectric liner is between the first dielectric liner and the first conductive contact, and wherein the first dielectric liner is separated from the first conductive contact by the third dielectric liner.

20. The method of claim 15, wherein a top surface of the source/drain region is concave after forming the first opening.
